(19) United States
(12) Patent Application Publication
(10) Pub. No.: US 2026/0331155 A1
(43) Pub. Date: Oct. 22, 2026

(54) SEMICONDUCTOR MEMORY DEVICE, METHOD FOR OPERATING THE SAME AND ELECTRONIC SYSTEM INCLUDING THE SAME

(71) Applicant: Samsung Electronics Co., Ltd., Suwon-si, Gyeonggi-do (KR)

(72) Inventors: Jun Yeong LIM, Suwon-si (KR); Seung Hyun KIM, Suwon-si (KR); Il Young LEE, Suwon-si (KR); Sung Duk HONG, Suwon-si (KR)

(21) Appl. No.: 19/337,125

(22) Filed: Sep. 23, 2025

(30) Foreign Application Priority Data
Apr. 16, 2025 (KR) 10-2025-0049339

(51) Int. Cl. G11C 11/22

(52) U.S. Cl. CPC G11C 11/2257; G11C 11/2273; G11C 11/2275

(57) ABSTRACT

A semiconductor memory device including a ferroelectrics-based data storage element, a method for operating the same, and an electronic system including the same are provided. The semiconductor memory device includes a plurality of word lines spaced apart from each other in a first direction, a semiconductor pattern extending in the first direction and intersecting the plurality of word lines, a data storage pattern including a ferroelectric material, between the plurality of word lines and the semiconductor pattern, a common source line connected to the semiconductor pattern, under the plurality of word lines, a bit line on the plurality of word lines, and a channel pad connecting the semiconductor pattern and the bit line, wherein each of the common source line and the channel pad includes a P-type semiconductor material.

### CROSS-REFERENCE TO RELATED APPLICATION

This application claims priority from Korean Patent Application No. 10-2025-0049339 filed on Apr. 16, 2025 in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor memory device, a method for operating the same, and an electronic system including the same. More specifically, the present disclosure relates to a semiconductor memory device including a ferroelectrics-based data storage element, a method for operating the same, and an electronic system including the same.

### BACKGROUND

As a semiconductor memory device capable of storing a high capacity of data therein is required in an electronic system, schemes for increasing a data storage capacity of the semiconductor memory device are being studied. A semiconductor memory device including memory cells arranged in a three-dimensional manner instead of memory cells arranged in a two-dimensional manner has been proposed as one of the schemes for increasing the data storage capacity of the semiconductor memory device.

### SUMMARY

Aspects of the present disclosure provide a semiconductor memory device with improved performance and reliability.

Aspects of the present disclosure provide a method for operating a semiconductor memory device with improved performance and reliability.

Aspects of the present disclosure provide an electronic system including a semiconductor memory device with improved performance and reliability.

Purposes according to the present disclosure are not limited to the above-mentioned purpose. Other purposes and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims and combinations thereof.

According to an aspect of the present inventive concept, there is provided a semiconductor memory device comprising a plurality of word lines spaced apart from each other in a first direction, a semiconductor pattern extending in the first direction and intersecting the plurality of word lines, a data storage pattern including a ferroelectric material, between the plurality of word lines and the semiconductor pattern, a common source line connected to the semiconductor pattern, under the plurality of word lines, a bit line on the plurality of word lines, and a channel pad connecting the semiconductor pattern and the bit line, wherein each of the common source line and the channel pad includes a P-type semiconductor material.

According to an aspect of the present inventive concept, there is provided a method for operating a semiconductor memory device, wherein the semiconductor memory device includes a plurality of word lines spaced apart from each other in a first direction, a semiconductor pattern extending in the first direction and intersecting the plurality of word lines, a data storage pattern including a ferroelectric material, between the plurality of word lines and the semiconductor pattern, and a bit line connected to the semiconductor pattern, on the plurality of word lines, the method comprising applying a negative erase voltage to the plurality of word lines to perform an erase operation on a plurality of memory cells corresponding to the plurality of word lines, applying a verification voltage to the plurality of word lines, and terminating the erase operation based on a current equal to or greater than a reference current being detected in the bit line as a result of the application of the verification voltage, wherein the semiconductor pattern is configured to form a P-type channel.

According to an aspect of the present inventive concept, there is provided an electronic system comprising a main substrate, a semiconductor memory device on the main substrate, and a controller electrically connected to the semiconductor memory device, on the main substrate, wherein the semiconductor memory devices includes: a plurality of word lines spaced apart from each other in a first direction, a semiconductor pattern extending in the first direction and intersecting the plurality of word lines, a data storage pattern including a ferroelectric material, between the plurality of word lines and the semiconductor pattern, a common source line connected to the semiconductor pattern, under the plurality of word lines, and a bit line on the plurality of word lines, wherein the semiconductor pattern is configured to form a P-type channel.

The specific details of other implementations are included in the detailed description and drawings.

### BRIEF DESCRIPTION OF DRAWINGS

The above and other aspects and features of the present disclosure will become more apparent by describing in detail implementations thereof with reference to the attached drawings, in which:

FIG. 1 is an illustrative block diagram for illustrating a semiconductor memory device according to some implementations.

FIG. 2 is an illustrative circuit diagram for illustrating a semiconductor memory device according to some implementations.

FIG. 3 is a schematic layout diagram for illustrating a semiconductor memory device according to some implementations.

FIG. 4 is a schematic cross-sectional view taken along a line A-A of FIG. 3.

FIG. 5 is an enlarged view for illustrating an area R1 of FIG. 4.

FIG. 6 is an example flowchart for illustrating an erase operation method of a semiconductor memory device according to some implementations.

FIGS. 7 to 13 are example diagrams for illustrating an erase operation method of a semiconductor memory device according to some implementations.

FIG. 14 is an example diagram for illustrating a program operation method of a semiconductor memory device according to some implementations.

FIG. 15 is an example diagram for illustrating a read operation method of a semiconductor memory device according to some implementations.

FIG. 16 is a schematic cross-sectional view for illustrating the semiconductor memory device according to some implementations.

FIG. 17 is an enlarged view for illustrating an area R2 of FIG. 16.

FIG. 18 is a schematic cross-sectional view for illustrating a semiconductor memory device according to some implementations.

FIG. 19 is an enlarged view for illustrating an area R3 of FIG. 18.

FIG. 20 is a schematic cross-sectional view for illustrating the semiconductor memory device according to some implementations.

FIGS. 21A and 21B are various enlarged views for illustrating an area S1 of FIG. 20.

FIGS. 22A and 22B are various enlarged views for illustrating an area S2 of FIG. 20.

FIGS. 23A, 23B, and 23C are various enlarged views for illustrating an area S3 of FIG. 20.

FIGS. 24A, 24B, and 24C are various enlarged views for illustrating an area S4 of FIG. 20.

FIG. 25 is an example block diagram for illustrating an electronic system according to some implementations.

FIG. 26 is an example perspective view illustrating an electronic system according to some implementations.

FIG. 27 is a schematic cross-sectional view taken along a line I-I of FIG. 26.

### DETAILED DESCRIPTIONS

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

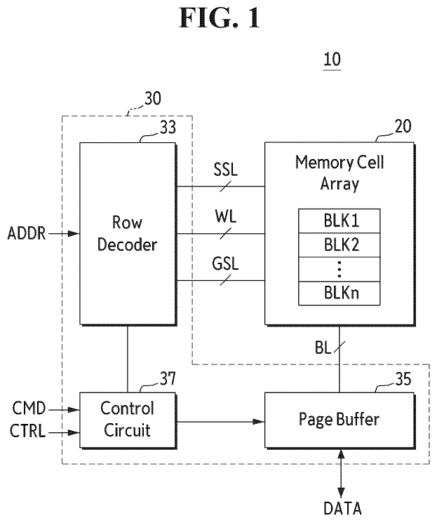

Hereinafter, referring to FIG. 1 to FIG. 5, a semiconductor memory device according to some implementations is described.

FIG. 1 is an illustrative block diagram for illustrating a semiconductor memory device according to some implementations.

The semiconductor memory device 10 may include a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 via a bit-line BL, a word-line WL, at least one string select line SSL, and at least one ground select line GSL. Specifically, the memory cell blocks BLK1 to BLKn may be connected to a row decoder 33 via the word-line WL, the string select line SSL and the ground select line GSL. Further, the memory cell blocks BLK1 to BLKn may be connected to a page buffer 35 via the bit-line BL.

The peripheral circuit 30 may receive an address ADDR, a command CMD, and a control signal CTRL from an external device to the semiconductor memory device 10, and may transmit and receive data DATA to and from an external device to the semiconductor memory device 10. The peripheral circuit 30 may include a control circuit 37, the row decoder 33, and the page buffer 35. The peripheral circuit 30 may further include various sub-circuits such as an input/output circuit, a voltage generation circuit for generating various voltages required for an operation of the semiconductor memory device 10, and an error correction circuit for correcting an error of the data DATA read from the memory cell array 20.

The control circuit 37 may be connected to the row decoder 33, the input/output circuit, and the voltage generation circuit. The control circuit 37 may control overall operations of the semiconductor memory device 10. The control circuit 37 may generate various internal control signals used in the semiconductor memory device 10 in response to the control signal CTRL. For example, the control circuit 37 may adjust a voltage level of a voltage supplied to the word-line WL and the bit-line BL when performing a memory operation such as a program operation or an erase operation.

The row decoder 33 may select at least one of the plurality of memory cell blocks BLK1 to BLKn in response to the address ADDR, and may select at least one word-line WL, at least one string select line SSL, and at least one ground select line GSL of the selected at least one memory cell block BLK1 to BLKn. Further, the row decoder 33 may transmit a voltage for performing a memory operation to the word-line WL of the selected at least one memory cell block BLK1 to BLKn.

The page buffer 35 may be connected to the memory cell array 20 via the bit-line BL. The page buffer 35 may operate as a writer driver or a sense amplifier. Specifically, when performing a program operation, the page buffer 35 operates as the writer driver to apply a voltage based on the data DATA to be stored in the memory cell array 20 to the bit-line BL. On the other hand, when performing a read operation, the page buffer 35 may operate as the sense amplifier to detect the data DATA stored in the memory cell array 20.

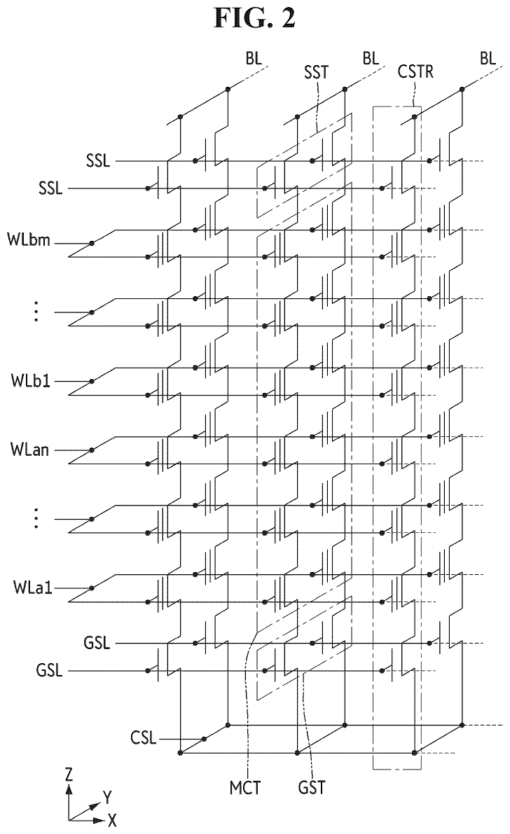

FIG. 2 is an illustrative circuit diagram for illustrating a semiconductor memory device according to some implementations.

Referring to FIG. 2, the memory cell array (e.g., 20 in FIG. 1) of the semiconductor memory device according to some implementations may include a common source line CSL, a plurality of bit-lines BL, and a plurality of cell strings CSTR.

The plurality of bit-lines BL may be two-dimensionally arranged in a plane defined by the first direction X and the second direction Y. For example, the bit-lines BL may be arranged and spaced apart from each other in the first direction X and extend in the second direction Y intersecting the first direction X. The plurality of cell strings CSTR may be connected in parallel to each of the bit-lines BL. The cell strings CSTR may be commonly connected to the common source line CSL. That is, the plurality of cell strings CSTR may be disposed between the bit-lines BL and the common source line CSL.

Each of the cell strings CSTR may include a ground select transistor GST connected to the common source line CSL, a string select transistor SST connected to the bit-line BL, and a plurality of memory cell transistors MCT disposed between the ground select transistor GST and the string select transistor SST. Each of the memory cell transistors MCT may include a data storage element. The ground select transistor GST, the string select transistor SST and the memory cell transistors MCT may be connected in series to each other in a vertical direction (hereinafter, a third direction Z). In accordance with the present disclosure, the third direction Z may interest (for example, substantially perpendicular to) the first direction X and the second direction Y.

The common source line CSL may be commonly connected to sources of the ground select transistors GST. Further, a ground select line GSL, a plurality of word-lines WLa1 to WLan and WLb1 to WLbm, and a string select line SSL may be disposed between the common source line CSL and the bit-line BL. The ground select line GSL may act as a gate electrode of the ground select transistor GST. The word-lines WLa1 to WLan and WLb1 to WLbm may be respectively used as gate electrodes of the memory cell transistors MCT. The string select line SSL may act as a gate electrode of the string select transistor SST.

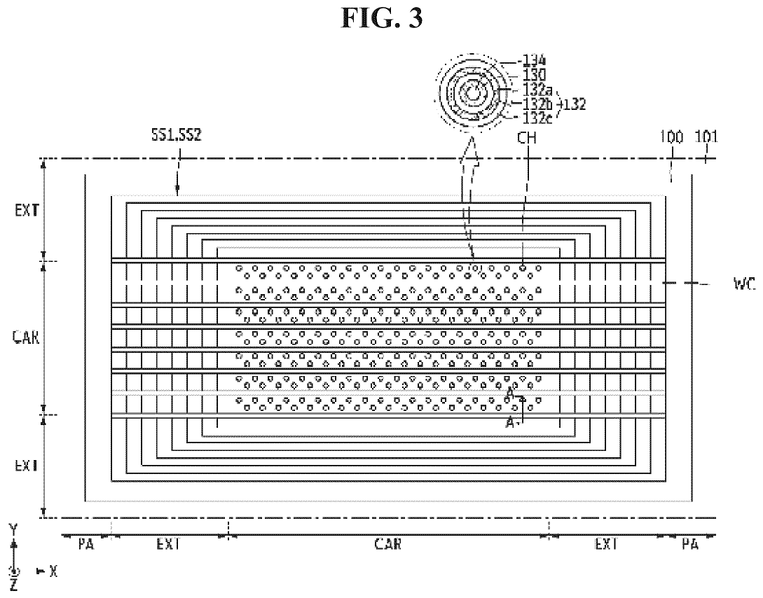

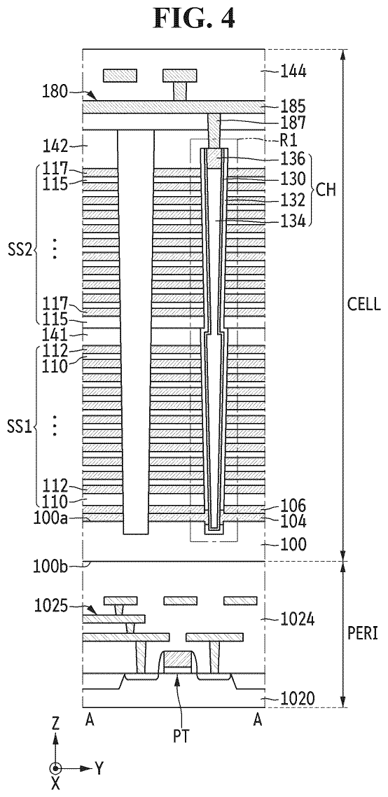

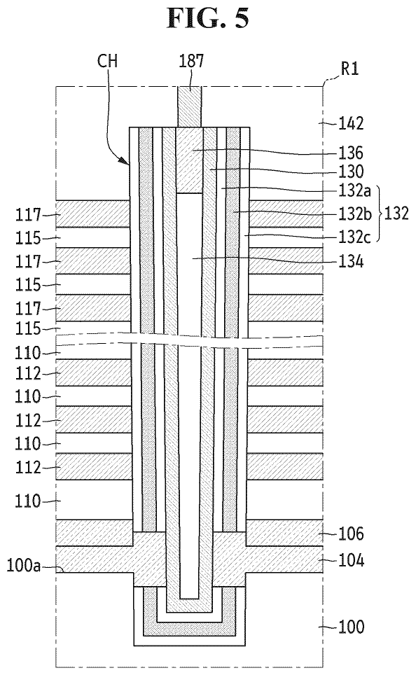

FIG. 3 is a schematic layout diagram for illustrating a semiconductor memory device according to some implementations. FIG. 4 is a schematic cross-sectional view taken along a line A-A of FIG. 3. FIG. 5 is an enlarged view for illustrating an area R1 of FIG. 4.

Referring to FIGS. 3 to 5, the semiconductor memory device according to some implementations may include a memory cell structure CELL and a peripheral circuit structure PERI.

The memory cell structure CELL may include a cell array area CAR, an extension area EXT, and a peripheral area PA.

A memory cell array (e.g., the memory cell array 20 of FIG. 1) including a plurality of memory cells may be formed in the cell array area CAR. For example, a source layer 104, gate electrodes 112 and 117, a channel structure CH, a conductive line 185, etc. which will be described later may be disposed in the cell array area CAR.

The extension area EXT may be disposed around the cell array area CAR. For example, the extension area EXT may be adjacent to the cell array area CAR in the first direction X. In some implementations, the gate electrodes 112 and 117 to be described later may be stacked in a stepwise manner in the extension area EXT.

The peripheral area PA may be a peripheral area surrounding the cell array area CAR and the extension area EXT. For example, the peripheral area PA may be adjacent to the cell array area CAR and/or the extension area EXT in the first direction X and/or the second direction Y.

The memory cell structure CELL may include a first substrate 100, a stack structure SS1 and SS2, an interlayer insulating film 141 and 142, a channel structure CH, a cutting pattern WC, and a first wiring structure 180.

The first substrate 100 may include, for example, a semiconductor substrate such as a silicon substrate, a germanium substrate, or a silicon-germanium substrate. Alternatively, the first substrate 100 may include a Silicon-On-Insulator (SOI) substrate or a Germanium-On-Insulator (GOI) substrate.

The first substrate 100 may include a first surface 100a and a second surface 100b opposite to each other. Each of the first surface 100a and the second surface 100b may extend along a horizontal plane (e.g., an XY plane). In the following description, the first surface 100a may also be referred to as a front surface or a front side of the first substrate 100, and the second surface 100b may also be referred to as a rear surface or a rear side or a back side or a back surface of the first substrate 100.

The stack structure SS1 and SS2 may be disposed in the cell array area CAR and the extension area EXT. The stack structure SS1 and SS2 may be formed on the first surface 100a of the first substrate 100. The stack structure SS1 and SS2 may include a plurality of mold insulating films 110 and 115 and a plurality of gate electrodes 112 and 117 stacked on the first substrate 100. Each of the mold insulating films 110 and 115 and each of the gate electrodes 112 and 117 may have a layered structure extending along a horizontal plane (e.g., an XY plane). The gate electrodes 112 and 117 may be sequentially stacked so as to be spaced apart from each other via each of the mold insulating films 110 and 115.

In some implementations, the stack structure SS1 and SS2 may include a plurality of gate stacks (e.g., a first gate stack SS1 and a second gate stack SS2) sequentially stacked on the first substrate 100. Although it is illustrated that the number of gate stacks stacked on the first substrate 100 is only two, this is only an example, and the number of gate stacks stacked on the first substrate 100 may be three or more.

The first gate stack SS1 may include first mold insulating films 110 and first gate electrodes 112 alternately stacked on top of each other on the first substrate 100. In some implementations, the first gate electrodes 112 may include at least one ground select line (e.g., GSL of FIG. 2) and a plurality of first word lines (e.g., WLa1 to WLan of FIG. 2) sequentially stacked on the first substrate 100. The numbers and shapes of the first mold insulating films 110 and the first gate electrodes 112 are merely examples, and are not limited to those illustrated.

The second gate stack SS2 may include second mold insulating films 115 and second gate electrodes 117 alternately stacked on top of each other on the first gate stack SS1. In some implementations, the second gate electrodes 117 may include a plurality of second word lines (e.g., WLb1 to WLbm of FIG. 2) and at least one string select line (e.g., SSL of FIG. 2) sequentially stacked on the first gate stack SS1. The numbers and shapes of the second mold insulating films 115 and the second gate electrodes 117 are merely examples, and are not limited to those illustrated.

Each of the gate electrodes 112 and 117 may include a conductive material, for example, a metal such as tungsten (W), molybdenum (Mo), ruthenium (Ru), cobalt (Co), nickel (Ni), or the like, or a semiconductor material such as silicon. However, implementations of the present disclosure are not limited thereto. For example, each of the gate electrodes 112 and 117 may include at least one of tungsten (W), molybdenum (Mo) and ruthenium (Ru). In another example, each of the gate electrodes 112 and 117 may include polysilicon.

In some implementations, each of the gate electrodes 112 and 117 may include a barrier metal film and a filling metal film which are sequentially stacked. The barrier metal film may include, for example, a metal nitride film such as a titanium nitride film (TiN). The filling metal film may fill an area of each of the gate electrodes 112 and 117 remaining after the barrier metal film has been formed therein.

Each of the mold insulating films 110 and 115 may include, for example, at least one of silicon oxide, silicon nitride, and silicon oxynitride. However, implementations of the present disclosure are not limited thereto. For example, each of the mold insulating films 110 and 115 may include a silicon oxide film.

The interlayer insulating film 141 and 142 may be formed on the first surface 100a of the first substrate 100 so as to cover the stack structure SS1 and SS2. For example, the first interlayer insulating film 141 may be formed on the first substrate 100 so as to cover the first gate stack SS1, and the second interlayer insulating film 142 may be formed on the first interlayer insulating film 141 so as to cover the second gate stack SS2. The interlayer insulating film 141 and 142 may include, for example, at least one of silicon oxide, silicon oxynitride, and a low dielectric constant (low-k) material having a lower dielectric constant than that of silicon oxide. However, implementations of the present disclosure are not limited thereto.

The channel structure CH may be disposed in the cell array area CAR. The channel structure CH may extend in the third direction Z so as to intersect the plurality of gate electrodes 112 and 117. For example, the channel structure CH may extend in the third direction Z to extend through the stack structure SS1 and SS2. The channel structure CH may be a structure having a pillar shape (e.g., a cylindrical shape) extending in the third direction Z.

In some implementations, the plurality of channel structures CH may be arranged in a zigzag manner in the plan view. For example, as illustrated in FIG. 3, the channel structures CH may be arranged in a staggered manner in each of the first direction X and the second direction Y. The channel structures CH having this arrangement may further improve the integration level of the semiconductor memory device. The number and arrangement of the channel structures CH are merely examples and are not limited to those shown.

In some implementations, each of the channel structures CH may have a step between the first gate stack SS1 and the second gate stack SS2. For example, as illustrated in FIG. 4, a side surface of each of the channel structures CH may have a bent portion at a boundary between the first interlayer insulating film 141 and the second gate stack SS2.

The channel structure CH may include a semiconductor pattern 130 and a data storage pattern 132.

The semiconductor pattern 130 may extend in the third direction Z so as to intersect the plurality of gate electrodes 112 and 117. Although the semiconductor pattern 130 is illustrated only in a shape of a cup, this is only an example. For example, the semiconductor pattern 130 may have various shapes such as a cylindrical shape, a rectangular column shape, a solid pillar shape, and the like. The semiconductor pattern 130 may include at least one of a semiconductor material, for example, single crystal silicon, polycrystalline silicon (polysilicon), an organic semiconductor material, a carbon nanostructure, or a combination thereof. However, implementations of the present disclosure are not limited thereto. For example, the semiconductor pattern 130 may include undoped silicon (Si).

The data storage pattern 132 may be interposed between the semiconductor pattern 130 and the plurality of gate electrodes 112 and 117. For example, the data storage pattern 132 may conformally extend along a profile of an outer surface of the semiconductor pattern 130.

The data storage pattern 132 may include ferroelectrics. The ferroelectrics may have a polarization, may change a direction of the polarization under an external electric field, and may have remnant polarization by the dipole even in a state in which the external electric field is not present. Each of the memory cells may store data therein using a polarization state of the data storage pattern 132.

In some implementations, the data storage pattern 132 may include a first insulating film 132a, a ferroelectric film 132b, and a second insulating film 132c, which are sequentially stacked on the outer surface of the semiconductor pattern 130.

The first insulating film 132a may be interposed between the semiconductor pattern 130 and the ferroelectric film 132b. For example, the first insulating film 132a may conformally extend along the profile of the outer surface of the semiconductor pattern 130. The first insulating film 132a may include, for example, at least one of silicon oxide, silicon nitride, silicon oxynitride, a high-k material (e.g., aluminum oxide (Al₂O₃) or hafnium oxide (HfO₂) or a combination thereof) having a higher dielectric constant than that of silicon oxide. For example, the first insulating film 132a may include a silicon oxide film. In some implementations, the first insulating film 132a may be omitted.

The ferroelectric film 132b may be interposed between the first insulating film 132a and the second insulating film 132c. For example, the ferroelectric film 132b may conformally extend along a profile of an outer surface of the first insulating film 132a. The ferroelectric film 132b may include, for example, at least one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, or a combination thereof. However, implementations of the present disclosure are not limited thereto. In some implementations, the ferroelectric film 132b may include hafnium-based ferroelectrics including hafnium (Hf).

The second insulating film 132c may be interposed between the ferroelectric film 132b and the gate electrodes 112 and 117. For example, the second insulating film 132c may conformally extend along the profile of the outer surface of the ferroelectric film 132b. The second insulating film 132c may be, for example, at least one of silicon oxide, silicon nitride, silicon oxynitride, a high-k material (e.g., aluminum oxide (Al₂O₃) or hafnium oxide (HfO₂) or a combination thereof) having a higher dielectric constant than that of silicon oxide. For example, the second insulating film 132c may include a silicon oxide film. In some implementations, the second insulating film 132c may be omitted.

In some implementations, the channel structure CH may further include a filling insulating film 134. The filling insulating film 134 may be formed to fill an inner space of the semiconductor pattern 130 having a cup shape. The filling insulating film 134 may include an insulating material, for example, silicon oxide. However, implementations of the present disclosure are not limited thereto.

In some implementations, the channel structure CH may further include a channel pad 136. The channel pad 136 may be formed to be in contact with and connected to one end (e.g., an upper end) of the semiconductor pattern 130. The channel pad 136 may include a conductive material, for example, polysilicon doped with an impurity, a metal or a metal silicide (silicide). However, implementations of the present disclosure are not limited thereto. The conductive line 185 may be electrically connected to the semiconductor pattern 130 via the channel pad 136.

In some implementations, a source layer 104 and a source support layer 106 may be formed between the first substrate 100 and the stack structure SS1 and SS2.

The source layer 104 may extend along the first surface 100a of the first substrate 100. The source layer 104 may be electrically connected to the semiconductor pattern 130. For example, the source layer 104 may extend through the data storage pattern 132 so as to contact the side surface of the semiconductor pattern 130. The source layer 104 may include a conductive material, for example, polysilicon doped with impurities, a metal, or a metal silicide (silicide). However, implementations of the present disclosure are not limited thereto. The source layer 104 may be provided as the common source line (e.g., CSL of FIG. 2) of the semiconductor memory device according to some implementations.

The source support layer 106 may be formed on the first substrate 100 and the source layer 104. For example, the source support layer 106 may extend along an upper surface of the source layer 104. The source support layer 106 may be used as a support to prevent fall down or collapse of the mold stack in a replacement process for forming the source layer 104. The source support layer 106 may include, for example, a polysilicon film. However, implementations of the present disclosure are not limited thereto.

The cutting pattern WC may be disposed across the cell array area CAR and the extension area EXT. The cutting pattern WC may extend in the first direction X so as to cut the stacked structure SS1 and SS2. In addition, the plurality of cutting patterns WC may extend in the first direction X and may be spaced apart from each other and arranged along the second direction Y. The stack structure SS1 and SS2 may be divided into a plurality of portions respectively constituting a plurality of memory cell blocks (e.g., BLK1 to BLKn of FIG. 1) via the plurality of cutting patterns WC. For example, two adjacent cutting patterns WC may define one memory cell block therebetween. A plurality of channel structures CH may be disposed in each memory cell blocks defined by the cutting patterns WC.

In some implementations, the cutting pattern WC may include an insulating material, for example, at least one of silicon oxide, silicon nitride, and/or silicon oxynitride. However, implementations of the present disclosure are not limited thereto. For example, the cutting pattern WC may include a silicon oxide film.

The first wiring structure 180 may be formed on the second interlayer insulating film 142. The first wiring structure 180 may be electrically connected to the source layer 104, the gate electrodes 112 and 117, and/or the channel structure CH. For example, the first inter-wiring insulating film 144 may be formed on the second interlayer insulating film 142. The first wiring structure 180 may be formed in the first inter-wiring insulating film 144 so as to be connected to the source layer 104, the gate electrodes 112 and 117, and/or the channel structure CH. The number of layers and the arrangement of the first wiring structure 180 are merely examples and are not limited to those shown.

The first wiring structure 180 may include a conductive material, for example, at least one of aluminum (Al), copper (Cu), tungsten (W), molybdenum (Mo), cobalt (Co), ruthenium (Ru), and alloys thereof. However, implementations of the present disclosure are not limited thereto.

In some implementations, the first wiring structure 180 may include the conductive line 185 disposed in the cell array area CAR. The conductive line 185 may extend in the second direction Y. In addition, each of the plurality of conductive lines 185 may extend in the second direction Y and the plurality of conductive lines 185 may be spaced apart from each other and arranged along the first direction X.

The conductive line 185 may be electrically connected to the plurality of channel structures CH arranged in the second direction Y. For example, a channel contact 187 extending in the third direction Z so as to connect the channel pad 136 and the conductive line 185 to each other may be formed. The conductive line 185 may be electrically connected to one end (e.g., an upper end) of the semiconductor pattern 130 via the channel contact 187 and the channel pad 136. The conductive line 185 may be provided as the bit line (e.g., the BL of FIG. 2) of the semiconductor memory device according to some implementations.

The semiconductor memory device according to some implementations may include memory cells based on a P-channel field effect transistor (PFET). That is, in each of the memory cells, the semiconductor pattern 130 may be configured to form a P-type channel. For example, each of the source layer 104 and the channel pad 136 may include an P-type semiconductor material. The source layer 104 and the channel pad 136 may include the same P-type semiconductor material or may include different P-type semiconductor materials. For example, each of the source layer 104 and the channel pad 136 may include polysilicon doped with P-type impurities. The P-type impurity may include at least one of boron (B), aluminum (Al), gallium (Ga), or indium (In). However, implementations of the present disclosure are not limited thereto.

The peripheral circuit structure PERI may include a second substrate 1020, a peripheral circuit element PT, and a second wiring structure 1025.

The second substrate 1020 may include, for example, a semiconductor substrate such as a silicon substrate, a germanium substrate, or a silicon-germanium substrate. Alternatively, the second substrate 1020 may include a SOI (Silicon-On-Insulator) substrate or a GOI (Germanium-On-Insulator) substrate.

The peripheral circuit element PT may be formed on the second substrate 1020. The peripheral circuit element PT may constitute a peripheral circuit (e.g., 30 of FIG. 1) that controls an operation of the semiconductor memory device. For example, the peripheral circuit element PT may include the control circuit (e.g., 37 of FIG. 1), the row decoder (e.g., 33 of FIG. 1), the page buffer (e.g., 35 of FIG. 1), etc. In the following description, a surface of the second substrate 1020 on which the peripheral circuit element PT is disposed may also be referred to as a front surface or a front side of the second substrate 1020. Conversely, the surface of the second substrate 1020 opposite to the front surface of the second substrate 1020 may also be referred to as a rear surface or side or a back surface or side of the second substrate 1020.

The peripheral circuit element PT may include, for example, a transistor. However, implementations of the present disclosure are not limited thereto. For example, the peripheral circuit element PT may include various active elements such as a transistor, as well as various passive elements such as a capacitor, a resistor, and an inductor.

The second wiring structure 1025 may be formed on the peripheral circuit element PT. For example, a second inter-wiring insulating film 1024 may be formed on the front surface of the second substrate 1020. The second wiring structure 1025 may be formed in the second inter-wiring insulating film 1024 and electrically connected to the peripheral circuit element PT. The number of layers and the arrangement of the second wiring structure 1025 shown are merely examples, and are not limited thereto.

In some implementations, the memory cell structure CELL may be stacked on the peripheral circuit structure PERI. For example, the memory cell structure CELL may be stacked on the second inter-wiring insulating film 1024.

In some implementations, the second surface 100b of the first substrate 100 may face the peripheral circuit structure PERI. For example, the first substrate 100 may be interposed between the stack structure SS1 and SS2 and the peripheral circuit structure PERI.

Hereinafter, a method for operating a semiconductor memory device according to example implementations will be described with reference to FIGS. 1 to 15. For convenience of description, contents duplicate with those described above with reference to FIGS. 1 to 5 will be briefly described or descriptions thereof will be omitted.

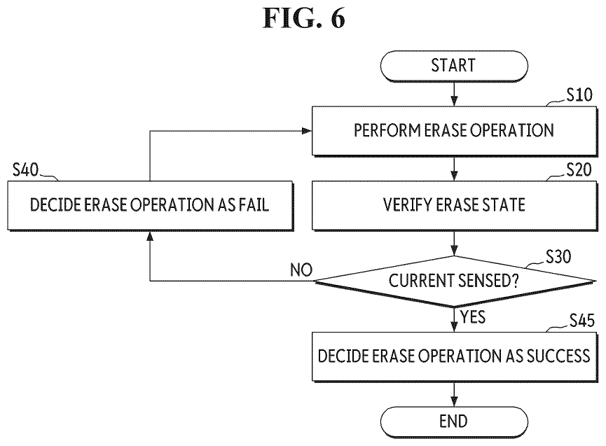

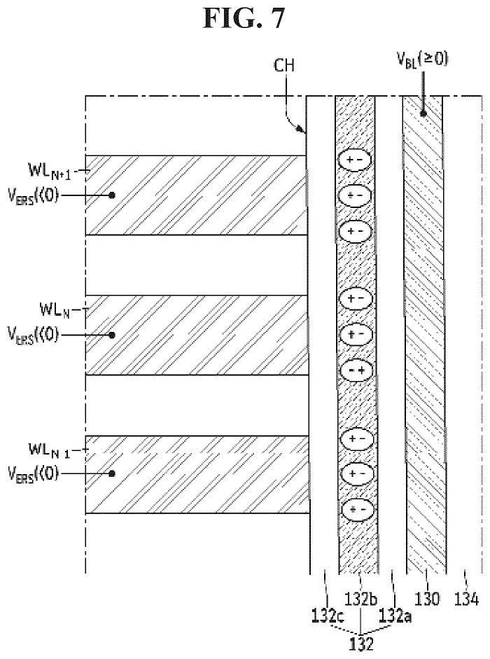

FIG. 6 is an example flowchart for illustrating an erase operation method of a semiconductor memory device according to some implementations. FIGS. 7 to 13 are example diagrams for illustrating an erase operation method of a semiconductor memory device according to some implementations.

Referring to FIGS. 6 and 7, an erase operation is performed on a plurality of memory cells corresponding to the plurality of word lines WL_{N-1}, WL_{N}, and WL_{N+1} in S10.

During the erase operation, a negative voltage may be applied to the plurality of word lines WL_{N-1}, WL_{N}, and WL_{N+1}. For example, the control circuit (e.g., 37 of FIG. 1) may be configured to apply an erase voltage V_{ERS} having a negative value to each of the word lines WL_{N-1}, WL_{N}, and WL_{N+1}.

As the erase operation is performed, as illustrated in FIG. 7, the dipoles of the data storage pattern 132 may be oriented such that a positive pole thereof is positioned to face toward the word lines WL_{N-1}, WL_{N}, and WL_{N+1} and a negative pole thereof is positioned to face toward the semiconductor pattern 130. Accordingly, the plurality of memory cells corresponding to the plurality of word lines WL_{N-1}, WL_{N}, and WL_{N+1} may be set as an erased state.

In some cases, at least some of the plurality of memory cells may not be sufficiently erased. In an example, as illustrated in FIG. 7, a memory cell corresponding to some (e.g., WL_{N-1} and/or WL_{N+1}) of the plurality of word lines WL_{N-1}, WL_{N}, and WL_{N+1} may be sufficiently erased to form a strongly erased cell (hereinafter, Hard ERS Cell), while a memory cell corresponding to the others (e.g., WL_{N}) of the plurality of word lines WL_{N-1}, WL_{N}, and WL_{N+1} may not be sufficiently erased to form a weakly erased cell (hereinafter, Soft ERS Cell).

In some implementations, during the erase operation, a ground voltage or a positive (+) voltage may be applied to the semiconductor pattern 130. For example, the control circuit (e.g., 37 of FIG. 1) may be configured to apply a bit line voltage V_{BL} having 0 or a positive (+) value to the bit line (e.g., 185 of FIG. 4) connected to the semiconductor pattern 130.

In some implementations, the erase operation may be performed on a block basis. For example, the erase operation may be individually performed on each of the memory cell blocks BLK1 to BLKn. A plurality of memory cells included in each of the memory cell blocks BLK1 to BLKn may be simultaneously erased by the erase operation.

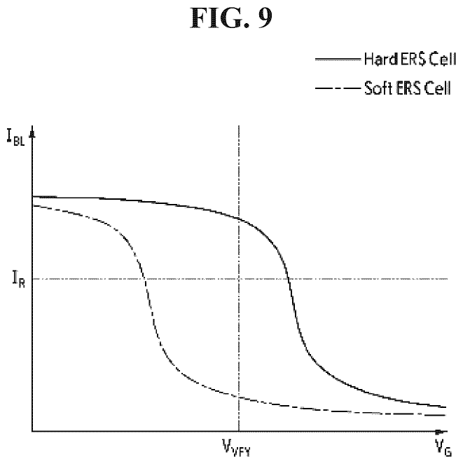

Referring to FIGS. 6, 8, and 9, an erased state of the plurality of memory cells is verified in S20. For reference, in FIG. 9, an x-axis represents a gate voltage V_{G} applied to the word line, and a y-axis represents a drain current I_{BL} sensed in the bit line.

In order to verify the erased state of the plurality of memory cells, a predetermined verification voltage V_{VFY} may be applied to the plurality of word lines WL_{N-1}, WL_{N}, and WL_{N+1}. For example, the control circuit (e.g., 37 of FIG. 1) may be configured to apply a predetermined verification voltage V_{VFY} to the plurality of word lines WL_{N-1}, WL_{N}, and WL_{N+1}.

The verification voltage V_{VFY} may be set to a value between a value of a threshold voltage of the strongly erased cell Hard ERS Cell and a value of a threshold voltage of the weakly erased cell Soft ERS Cell. Specifically, as described above, the semiconductor pattern 130 of each of the memory cells may be configured to form the P-type channel. Accordingly, as illustrated in FIG. 9, each of the memory cells MC may have a characteristic in which the value of the drain current I_{BL} decreases as the value of the gate voltage V_{G} increases (i.e., in the positive (+) direction). In addition, as illustrated in FIG. 9, the threshold voltage of the strongly erased cell Hard ERS Cell may be greater than the threshold voltage of the weakly erased cell Soft ERS Cell. In this case, the verification voltage V_{VFY} may be set to a value lower than a threshold voltage of the strongly erased cell Hard ERS Cell and higher than a threshold voltage of the weakly erased cell Soft ERS Cell.

In some implementations, the verification voltage V_{VFY} may have a positive (+) value. For example, the threshold voltage of the strongly erased cell Hard ERS Cell may have a positive (+) value.

In some implementations, a ground voltage or a negative voltage may be applied to the semiconductor pattern 130 to verify the erased state of the plurality of memory cells. For example, the control circuit (e.g., 37 of FIG. 1) may be configured to apply a bit line voltage VBL having 0 or a negative (−) value to the bit line (e.g., 185 of FIG. 4) connected to the semiconductor pattern 130.

Subsequently, it is determined whether a current of a predetermined level or higher is sensed in the bit line (e.g., BL of FIG. 2) in S30. In response to determining (by the control circuit) that no current of the predetermined level or higher is detected in the bit line (e.g., BL of FIG. 2), it may be determined that the erase operation has failed in S40.

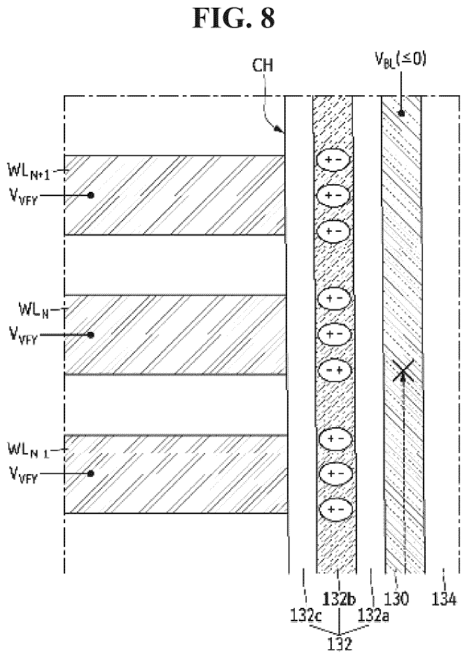

In an example, as illustrated in FIGS. 8 and 9, some of the plurality of memory cells may form the strongly erased cell Hard ERS Cell, and the others of the plurality of memory cells may form the weakly erased cell Soft ERS Cell. Since the verification voltage V_{VFY} is lower than the threshold voltage of the strongly erased cell Hard ERS Cell, the strongly erased cell Hard ERS Cell may be turned on to form the P-type channel in the semiconductor pattern 130. However, since the verification voltage V_{VFY} is greater than the threshold voltage of the weakly erased cell Soft ERS Cell, the weakly erased cell Soft ERS Cell may be turned off such that the P-type channel is not formed in the semiconductor pattern 130. Accordingly, a current equal to or greater than a predetermined reference current I_{R} may not be sensed in the bit line (e.g., BL of FIG. 2), and it may be determined that the erase operation has failed. That is, when at least one of the plurality of memory cells corresponding to the plurality of word lines WL_{N-1}, WL_{N}, and WL_{N+1} is not sufficiently erased (or when at least one of the plurality of memory cells forms the weakly erased cell (Soft ERS Cell)), it may be determined that the erase operation has failed.

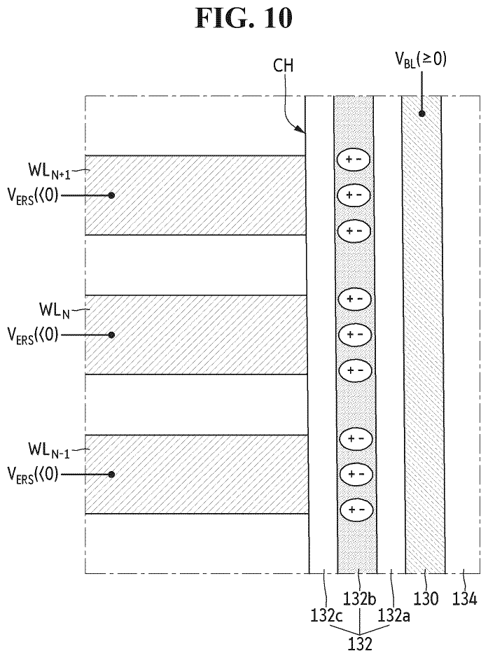

Referring to FIGS. 6 and 10, when it is determined that the erase operation has failed in S40, the erase operation is repeated. That is, step S10 of performing the erase operation on the plurality of memory cells corresponding to the plurality of word lines WL_{N-1}, WL_{N}, and WL_{N+1} may be performed again.

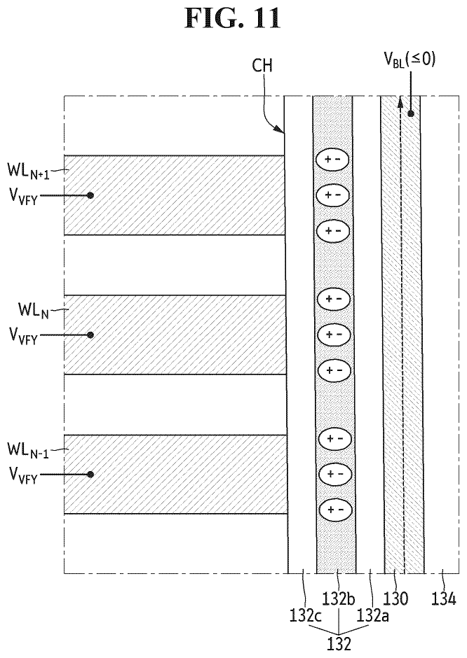

Referring to FIGS. 6 and 11, step S20 of verifying the erased state of the plurality of memory cells may be performed again. Subsequently, step S30 of determining whether the current of the predetermined level or higher is sensed in the bit line (e.g., BL of FIG. 2) may be performed again. When the current of the predetermined level or higher is detected in the bit line (e.g., BL of FIG. 2), the erase operation may be determined to be successful in S45.

For example, as illustrated in FIGS. 9 and 11, all of the plurality of memory cells may form the strongly erased cell Hard ERS Cell. Since the verification voltage V_{VFY} is lower than the threshold voltage of the strongly erased cell Hard ERS Cell, the strongly erased cell Hard ERS Cell may be turned on to form the P-type channel in the semiconductor pattern 130. Accordingly, a current equal to or greater than the predetermined reference current I_{R} may be sensed in the bit line (e.g., BL of FIG. 2), and the erase operation may be determined to be successful. That is, when a plurality of memory cells corresponding to the plurality of word lines WL_{N-1}, WL_{N} and WL_{N+1} are sufficiently erased (or when all of the plurality of memory cells form the strongly erased cell Hard ERS Cell), the erase operation may be determined to be successful and may be terminated.

As the semiconductor memory device becomes increasingly highly integrated, a ferroelectric memory cell including a ferroelectrics-based data storage device is being studied. In the semiconductor memory device including memory cells arranged in a three-dimensional manner, the ferroelectric memory cell may be advantageous in reducing a cross-sectional area of the cell string (e.g., CSTR of FIG. 2).

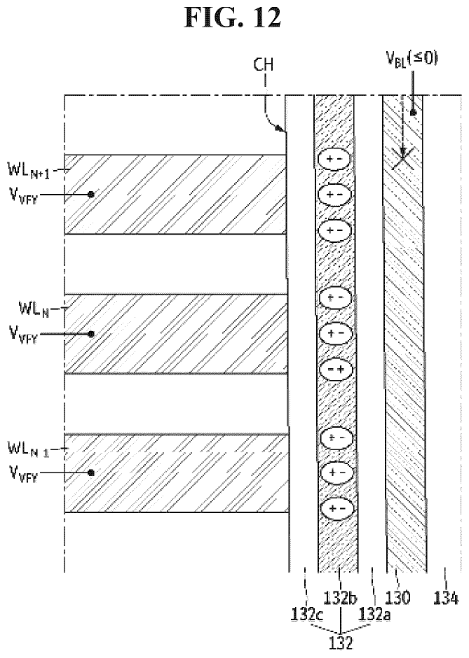

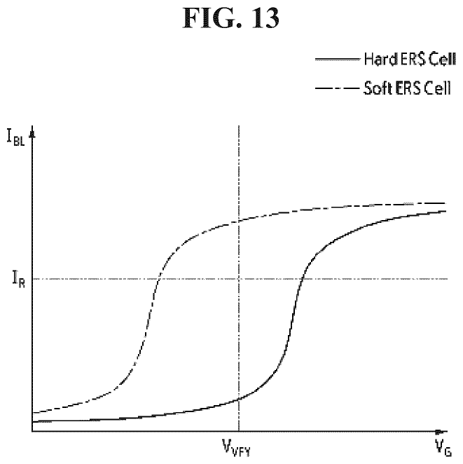

However, in an N-channel Field Effect Transistor (NFET)-based ferroelectric memory cell, it is difficult to verify the erased state thereof. FIG. 12 illustrates a step of verifying an erased state of each of the memory cells when the semiconductor pattern 130 of each of the memory cells is configured to form an N-type channel. In addition, in FIG. 13, the x-axis represents the gate voltage V_{G} applied to the word line, and the y-axis represents the drain current I_{BL} sensed in the bit line.

First, in order to verify the erased state of the NFET-based ferroelectric memory cells, the predetermined verification voltage V_{VFY} may be applied to the plurality of word lines WL_{N-1}, WL_{N}, and WL_{N+1}.

The verification voltage V_{VFY} may be set to a value between a value of a threshold voltage of the strongly erased cell Hard ERS Cell and a value of a threshold voltage of the weakly erased cell Soft ERS Cell. Specifically, as described above, the semiconductor pattern 130 of each of the memory cells may be configured to form an N-type channel. Accordingly, as illustrated in FIG. 13, each of the memory cells may have a characteristic in which the value of the drain current I_{BL} increases as the value of the gate voltage V_{G} increases (i.e., in the positive (+) direction). In addition, as illustrated in FIG. 13, the threshold voltage of the strongly erased cell Hard ERS Cell may be greater than the threshold voltage of the weakly erased cell Soft ERS Cell. In this case, the verification voltage V_{VFY} may be set to a value lower than the threshold voltage of the strongly erased cell Hard ERS Cell and higher than the threshold voltage of the weakly erased cell Soft ERS Cell.

Subsequently, it may be determined whether the current of the predetermined level or higher is sensed in the bit line (e.g., BL of FIG. 2).

For example, as illustrated in FIGS. 12 and 13, some of the plurality of memory cells may form the strongly erased cell Hard ERS Cell, and the others of the plurality of memory cells may form the weakly erased cell Soft ERS Cell. Since the verification voltage V_{VFY} is greater than the threshold voltage of the weakly erased cell Soft ERS Cell, the weakly erased cell Soft ERS Cell may be turned on to form an N-type channel in the semiconductor pattern 130. However, the verification voltage V_{VFY} is lower than the threshold voltage of the strongly erased cell Hard ERS Cell, such that the strongly erased cell Hard ERS Cell may be turned off and thus the N-type channel may not be formed in the semiconductor pattern 130. That is, when at least one of the plurality of memory cells corresponding to the plurality of word lines WL_{N-1}, WL_{N}, and WL_{N+1} is sufficiently erased (or when at least one of the plurality of memory cells forms the strongly erased cell Hard ERS Cell), a current equal to or greater than the predetermined reference current I_{R} may not be sensed in the bit line BL of FIG. 2. Accordingly, the erase operation may be determined as being successful regardless of whether the memory cell (the weakly erased cell (Soft ERS Cell)) that is not sufficiently erased exists.

Alternatively, the semiconductor memory device according to some implementations may easily verify an erased state using the PFET-based ferroelectric memory cells. Specifically, as described above, the semiconductor pattern 130 of each memory cell is configured to form the P-type channel. Thus, when at least one of the plurality of memory cells corresponding to the plurality of word lines WL_{N-1}, WL_{N}, and WL_{N+1} is not sufficiently erased (or when at least one of the plurality of memory cells forms the weakly erased cell Soft ERS Cell), it may be determined that the erase operation has failed. That is, the erased state of the plurality of memory cells may be verified based on the amount of current sensed in the bit line (e.g., BL of FIG. 2). Accordingly, the semiconductor memory device with improved performance and reliability and an operating method thereof may be provided.

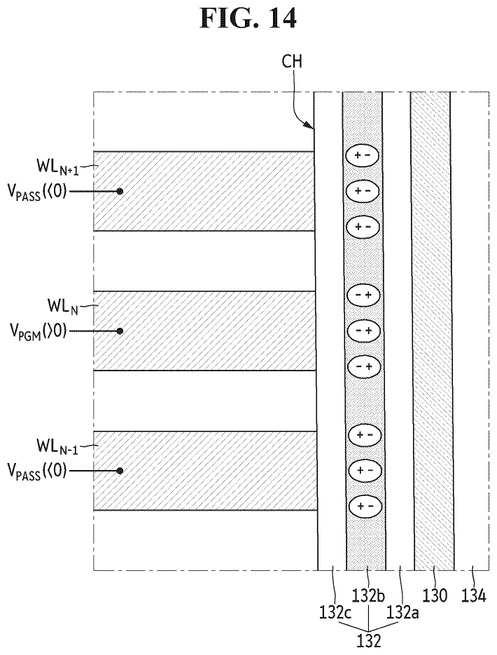

FIG. 14 is an example diagram for illustrating a program operation method of a semiconductor memory device according to some implementations. For convenience of description, contents duplicate with those described above with reference to FIGS. 1 to 13 will be briefly described or descriptions thereof will be omitted.

Referring to FIG. 14, a program operation is performed on a target memory cell corresponding to a selected word line WL_{N} among the plurality of word lines WL_{N-1}, WL_{N}, and WL_{N+1}.

During the program operation, a positive voltage may be applied to the selected word line WL_{N}. For example, the control circuit (e.g., 37 of FIG. 1) may be configured to apply a program voltage V_{PGM} having a positive (+) value to the selected word line WL_{N}, and may be configured to apply a pass voltage V_{PASS} having a negative (−) value to the unselected word line WL_{N-1} and WL_{N+1}.

As the program operation is performed, the dipoles of the data storage pattern 132 may be oriented such that the negative pole thereof is positioned to face toward the selected word line WL_{N} and the positive pole thereof is positioned to face toward the semiconductor pattern 130, as illustrated. Accordingly, the target memory cell corresponding to the selected word line WL_{N} may be set as a programmed state. As the semiconductor pattern 130 is configured to form the P-type channel, the pass voltage V_{PASS} may be set to a value lower than a value of a threshold voltage of the memory cell in the programmed state.

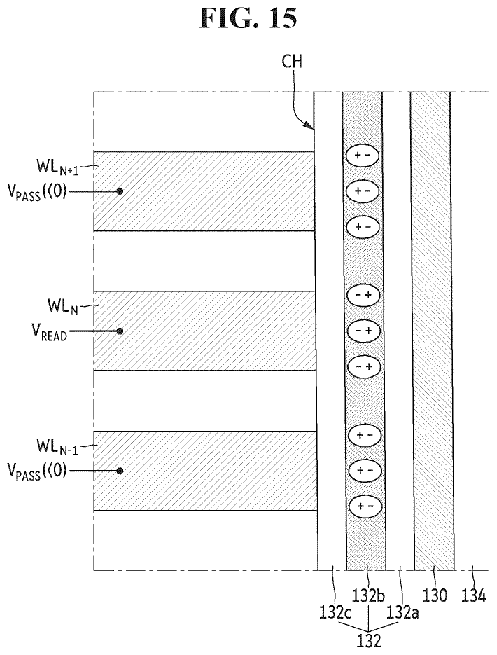

FIG. 15 is an example diagram for illustrating a read operation method of a semiconductor memory device according to some implementations. For convenience of description, contents duplicate with those described above with reference to FIGS. 1 to 14 will be briefly described or descriptions thereof will be omitted.

Referring to FIG. 15, a read operation is performed on a target memory cell corresponding to a selected word line WL_{N} among the plurality of word lines WL_{N-1}, WL_{N}, and WL_{N+1}.

In order to read data stored in the target memory cell, a predetermined read voltage V_{READ} may be applied to the selected word line WL_{N}. For example, the control circuit (e.g., 37 of FIG. 1) may be configured to apply the predetermined read voltage V_{READ} to the selected word line WL_{N}, and may be configured to apply the pass voltage V_{PASS} having a negative value to the unselected word lines WL_{N-1} and WL_{N+1}.

The read voltage V_{READ} may be set to a value between a value of a threshold voltage of a memory cell in an erased state and a value of a threshold voltage of a memory cell in a programmed state. Specifically, as the semiconductor pattern 130 is configured to form the P-type channel, the read voltage V_{READ} may be set to a value greater than a threshold voltage of a memory cell in a programmed state and lower than a threshold voltage of a memory cell in an erased state. In some implementations, the read voltage V_{READ} may have a negative (−) value. In addition, the pass voltage V_{PASS} may be set to a value lower than a value of a threshold voltage of a memory cell in a programmed state.

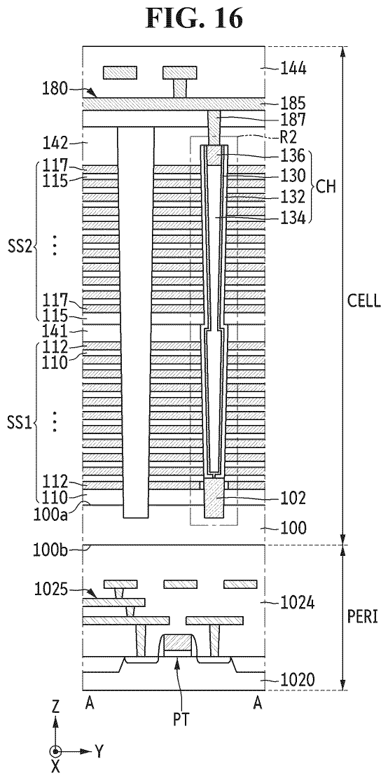

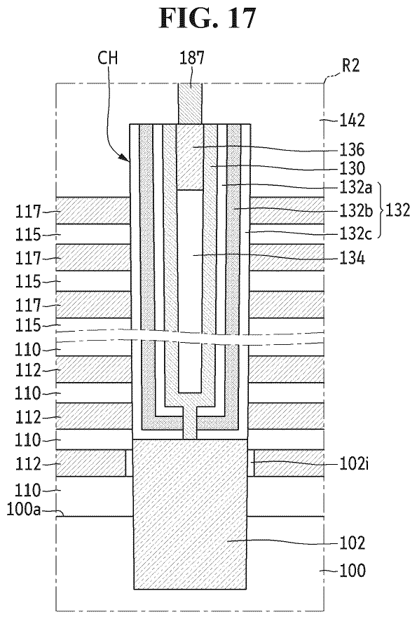

FIG. 16 is a schematic cross-sectional view for illustrating the semiconductor memory device according to some implementations. FIG. 17 is an enlarged view for illustrating an area R2 of FIG. 16. For convenience of description, contents duplicate with those described above with reference to FIGS. 1 to 15 will be briefly described or descriptions thereof will be omitted.

Referring to FIGS. 16 and 17, the semiconductor memory device according to some implementations includes a source pattern 102.

The source pattern 102 may be formed on the first substrate 100. The source pattern 102 may be interposed between the first substrate 100 and the semiconductor pattern 130 and between the first substrate 100 and the data storage pattern 132. The source pattern 102 may be electrically connected to the semiconductor pattern 130. For example, one end (e.g., a lower end) of the semiconductor pattern 130 may extend through a lower portion of the data storage pattern 132 so as to contact the source pattern 102. The source pattern 102 may be provided as the common source line (e.g., the CSL of FIG. 2) of the semiconductor device according to some implementations.

In some implementations, the source pattern 102 may be formed from the first substrate 100 in SEG (Selective Epitaxial Growth) process. In some implementations, the source pattern 102 may be formed at a higher vertical level than that of an upper surface of a lowermost gate electrode disposed at a lowermost level among the first gate electrodes 112. In some implementations, the source pattern 102 may be spaced apart from the lowermost gate electrode GE2 via a side insulating film 102i.

The semiconductor memory device according to some implementations may include PFET-based memory cells. That is, in each of the memory cells, the semiconductor pattern 130 may be configured to form an P-type channel. For example, each of the source pattern 102 and the channel pad 136 may include a P-type semiconductor material. The source pattern 102 and the channel pad 136 may include the same P-type semiconductor material or may include different P-type semiconductor materials. For example, each of the source pattern 102 and the channel pad 136 may include polysilicon doped with P-type impurities. The P-type impurity may include at least one of boron (B), aluminum (Al), gallium (Ga), or indium (In). However, implementations of the present disclosure are not limited thereto.

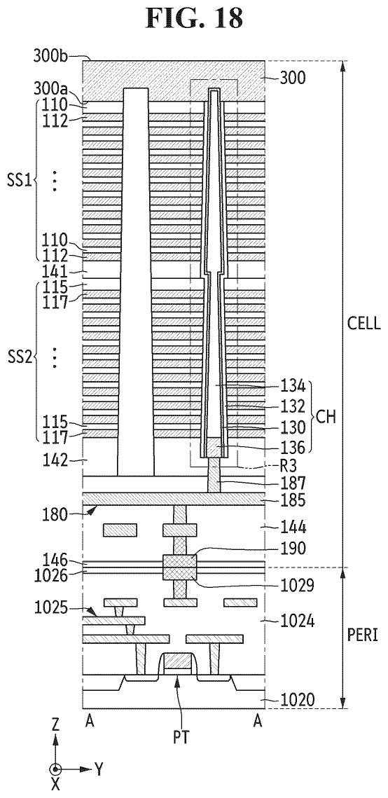

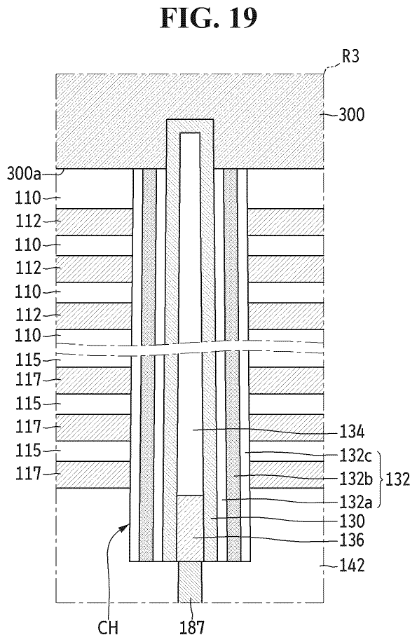

FIG. 18 is a schematic cross-sectional view for illustrating a semiconductor memory device according to some implementations. FIG. 19 is an enlarged view for illustrating an area R3 of FIG. 18. For convenience of description, contents duplicate with those described above with reference to FIGS. 1 to 17 will be briefly described or descriptions thereof will be omitted.

Referring to FIGS. 18 and 19, the semiconductor memory device according to some implementations includes a source substrate 300.

The source substrate 300 may include a third surface 300a and a fourth surface 300b opposite to each other. Each of the third surface 300a and the fourth surface 300b may extend along a horizontal plane (e.g., an XY plane). The stack structure SS1 and SS2 may be formed on the third surface 300a of the source substrate 300. The source substrate 300 may be electrically connected to the semiconductor pattern 130. For example, one end (e.g., an upper end) of the semiconductor pattern 130 may extend through an upper portion of the data storage pattern 132 so as to be in contact with the source substrate 300. The source substrate 300 may be provided as the common source line (e.g., the CSL of FIG. 2) of the semiconductor device according to some implementations.

In some implementations, the third surface 300a of the source substrate 300 may face the peripheral circuit structure PERI. For example, the semiconductor device according to some implementations may have a C2C (chip to chip) structure. The C2C structure means that an upper chip including a memory cell structure CELL is fabricated on a first wafer, a lower chip including a peripheral circuit structure PERI is fabricated on a second wafer different from the first wafer, and then the upper chip and the lower chip are connected to each other in a bonding manner.

In one example, the bonding manner may mean a scheme of electrically or physically connecting a first bonding metal 190 (and/or a first bonding insulating film 146) formed in the uppermost metal layer of the upper chip and a second bonding metal 1029 (and/or a second bonding insulating film 1026) formed in the uppermost metal layer of the lower chip to each other. For example, when the first bonding metal 190 and the second bonding metal 1029 are made of copper (Cu), the bonding scheme may be a Cu—Cu bonding scheme. However, this is merely an example, and the first bonding metal 190 and the second bonding metal 1029 may be made of various other metals such as aluminum (Al) or tungsten (W).

As the first bonding metal 190 and the second bonding metal 1029 are bonded to each other, the first wiring structure 180 may be electrically connected to the second wiring structure 280. Accordingly, the plurality of memory cells formed in the cell array area CAR may be electrically connected to the peripheral circuit element PT.

The semiconductor memory device according to some implementations may include PFET-based memory cells. That is, in each of the memory cells, the semiconductor pattern 130 may be configured to form an P-type channel. For example, each of the source substrate 300 and the channel pad 136 may include a P-type semiconductor material. The source substrate 300 and the channel pad 136 may include the same P-type semiconductor material or may include different P-type semiconductor materials. For example, each of the source substrate 300 and the channel pad 136 may include polysilicon doped with P-type impurities. The P-type impurity may include at least one of boron (B), aluminum (Al), gallium (Ga), or indium (In). However, implementations of the present disclosure are not limited thereto.

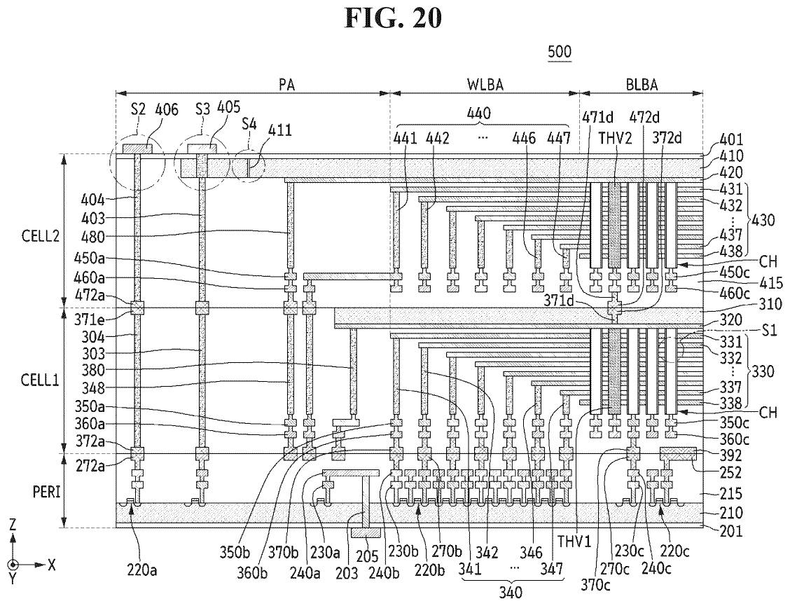

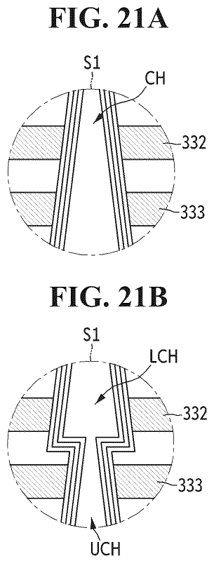

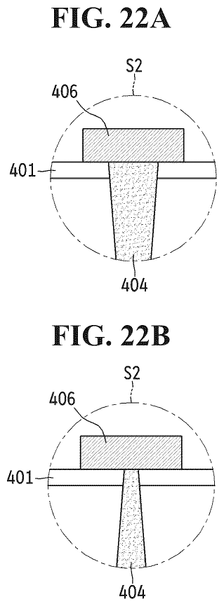

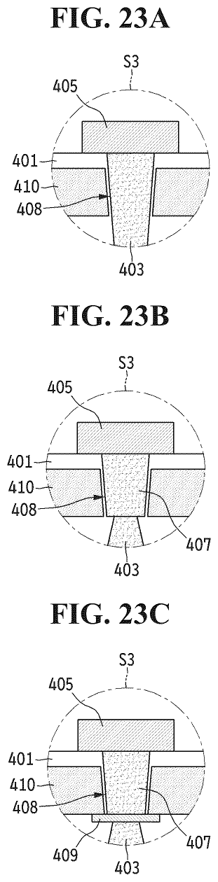

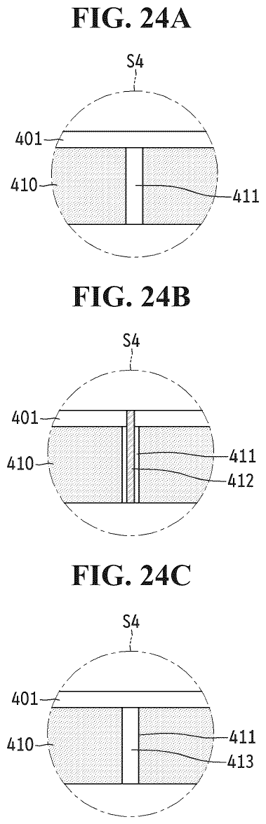

FIG. 20 is a schematic cross-sectional view for illustrating the semiconductor memory device according to some implementations. FIGS. 21A and 21B are various enlarged views for illustrating an area S1 of FIG. 20. FIGS. 22A and 22B are various enlarged views for illustrating an area S2 of FIG. 20. FIGS. 23A to 23C are various enlarged views for illustrating an area S3 of FIG. 20. FIGS. 24A to 24C are various enlarged views for illustrating an area S4 of FIG. 20. For convenience of description, contents duplicate with those described above with reference to FIGS. 1 to 19 will be briefly described or descriptions thereof will be omitted.

Referring to FIG. 20, the semiconductor memory device 500 may have a chip to chip (C2C) structure.

The semiconductor memory device 500 may include at least one or more upper chips including the cell structure. For example, as illustrated in FIG. 20, the semiconductor memory device 500 may be implemented to include two upper chips. However, this is merely illustrative, and the number of upper chips is not limited thereto. When the semiconductor memory device 500 is implemented to include two upper chips, the semiconductor memory device 500 may be manufactured by manufacturing a first upper chip including a first cell structure CELL1, a second upper chip including a second cell structure CELL2, and a lower chip including a peripheral circuit structure PERI, respectively, and then connecting the first upper chip, the second upper chip, and the lower chip to each other in a bonding manner. The first upper chip may be turned upside down and be connected to the lower chip in a bonding manner, and the second upper chip may also be turned upside down and be connected to the first upper chip in a bonding manner. In the following description, upper and lower surfaces of the first and second upper chips are defined based on a state before each of the first and second upper chips is turned upside down. That is, in FIG. 20, the upper portion of the lower chip may refer to an upper portion defined based on the +Z-axis direction, and the upper portion of each of the first and second upper chips may refer to an upper portion defined based on the −Z-axis direction. However, this is merely example, and only one of the first upper chip and the second upper chip may be turned upside down and the upper and lower chips may be connected to each other in a bonding manner.

Each of the peripheral circuit structure PERI and the first and second cell structures CELL1 and CELL2 of the semiconductor memory device 500 may include an external pad peripheral area PA, a word line bonding area WLBA, and a bit line bonding area BLBA.

The peripheral circuit structure PERI may include a third substrate 210 and a plurality of circuit elements 220a, 220b, and 220c formed on the third substrate 210. An interlayer insulating layer 215 including one or more insulating layers may be disposed on the plurality of circuit elements 220a, 220b, and 220c. A plurality of metal lines connecting the plurality of circuit elements 220a, 220b, and 220c to each other may be disposed in the interlayer insulating layer 215. For example, the plurality of metal lines may include first metal wirings 230a, 230b, and 230c connected to the plurality of circuit elements 220a, 220b, and 220c, respectively, and second metal wirings 240a, 240b, and 240c respectively formed on the first metal wirings 230a, 230b, and 230c. The plurality of metal wirings may be made of at least one of various conductive materials. For example, the first metal wiring 230a, 230b, and 230c may be made of tungsten having a relatively high electrical resistivity, and the second metal wiring 240a, 240b, and 240c may be made of copper having a relatively low electrical resistivity.

Herein, only the first metal wirings 230a, 230b, and 230c and the second metal wirings 240a, 240b, and 240c are illustrated and described. However, the present disclosure is not limited thereto, and at least one additional metal wiring may be further formed on the second metal wirings 240a, 240b, and 240c. In this case, the second metal wirings 240a, 240b, and 240c may be made of aluminum. In addition, at least some of the additional metal wirings formed on the second metal wirings 240a, 240b, and 240c may be made of copper having a lower electrical resistivity than that of the aluminum of the second metal wiring 240a, 240b, and 240c.

The interlayer insulating layer 215 may be disposed on the third substrate 210 and may include an insulating material such as silicon oxide, silicon nitride, or the like.

Each of the first and second cell structures CELL1 and CELL2 may include at least one memory block. The first cell structure CELL1 may include a fourth substrate 310 and a common source line 320. A plurality of word lines 331 to 338 and 330 may be stacked on the fourth substrate 310 in a direction (Z-axis direction) perpendicular to the upper surface of the fourth substrate 310. The string select lines and the ground select line may be respectively disposed on top of and under the word lines 330, and the plurality of word lines 330 may be disposed between the string select lines and the ground select line. Similarly, the second cell structure CELL2 may include a fifth substrate 410 and a common source line 420, and a plurality of word lines 431 to 438 and 430 may be stacked along a direction (Z-axis direction) perpendicular to the upper surface of the fifth substrate 410. The fourth substrate 310 and the fifth substrate 410 may be made of various materials, and may be, for example, a silicon substrate, a silicon-germanium substrate, a germanium substrate, or a substrate having a monocrystalline silicon substrate and a single crystal epitaxial layer grown on the monocrystalline silicon substrate. A plurality of channel structures CH may be formed in each of the first and second cell structures CELL1 and CELL2.

In some implementations, as illustrated in FIG. 21A, the channel structure CH may be provided in the bit line bonding area BLBA, and may extend in a direction perpendicular to the upper surface of the fourth substrate 310 so as to extend through the word lines 330, the string select lines, and the ground select line. The channel structure CH may include a data storage layer, a channel layer, a buried insulating layer, etc. The channel layer CH may be electrically connected to a first metal wiring 350c and a second metal wiring 360c in the bit line bonding area BLBA. For example, the second metal wiring 360c may be a bit line, and may be connected to the channel structure CH via the first metal wiring 350c. The bit line 360c may extend along a second direction Y parallel to the upper surface of the fourth substrate 310.

In some implementations, as illustrated in FIG. 21B, the channel structure CH may include a lower channel LCH and an upper channel UCH connected to each other. For example, the channel structure CH may be formed in a process for forming the lower channel LCH and a process for forming the upper channel UCH. The lower channel LCH may extend in a direction perpendicular to the upper surface of the fourth substrate 310 so as to extend through the common source line 320 and the lower word lines 331 and 332. The lower channel LCH may include a data storage layer, a channel layer, a buried insulating layer, etc., and may be connected to the upper channel UCH. The upper channel UCH may extend through the upper word lines 333 to 338. The upper channel UCH may include a data storage layer, a channel layer, a buried insulating layer, etc., and the channel layer of the upper channel UCH may be electrically connected to the first metal wiring 350c and the second metal wiring 360c. As the length of the channel increases, it may become difficult to form a channel having an uniform width due to a reason in terms of a process. The semiconductor memory device 500 according to an implementation of the present disclosure may include a channel having improved width uniformity using the lower channel LCH and the upper channel UCH formed sequentially.

When the channel structure CH is formed to include the lower channel LCH and the upper channel UCH as illustrated in FIG. 21B, the word line located near a boundary between the lower channel LCH and the upper channel UCH may be a dummy word line. For example, the word line 332 and the word line 333 defining the boundary between the lower channel LCH and the upper channel UCH may be dummy word lines. In this case, data may not be stored in memory cells connected to the dummy word line. Alternatively, the number of pages page corresponding to memory cells connected to the dummy word line may be smaller than the number of pages corresponding to memory cells connected to a general word line. A voltage level applied to the dummy word line may be different from a voltage level applied to the general word line, and accordingly, an influence of a difference between channel widths of the lower channel LCH and the upper channel UCH on the operation of the memory device may be reduced.

In an example, in FIG. 21B, it is illustrated that the number of the lower word lines 331 and 332 through which the lower channel LCH extends is smaller than the number of the upper word lines 333 to 338 through which the upper channel UCH extends. However, this is merely an example, and the present disclosure is not limited thereto. In another example, the number of the lower word lines which the lower channel LCH extends through may be equal to or greater than the number of the upper word lines which the upper channel UCH extends through. In addition, the structure and the connection relationship of the channel structure CH disposed in the first cell structure CELL1 as described above may be equally applied to the channel structure CH disposed in the second cell structure CELL2.

In the bit line bonding area BLBA, a first through-electrode THV1 may be provided in the first cell structure CELL1, and a second through-electrode THV2 may be provided in the second cell structure CELL2. As illustrated in FIG. 20, the first through-electrode THV1 may extend through the common source line 320 and the plurality of word lines 330. However, this is merely an example, and the first through-electrode THV1 may further extend through the fourth substrate 310. The first through-electrode THV1 may include a conductive material. Alternatively, the first through-electrode THV1 may include a conductive material surrounded with an insulating material. The second through-electrode THV2 may also be provided in the same shape and structure as those of the first through-electrode THV1.

In some implementations, the first through-electrode THV1 and the second through-electrode THV2 may be electrically connected to each other via a first through-metal pattern 372d and a second through-metal pattern 472d. The first through-metal pattern 372d may be formed at a lower end of the first upper chip UC1 including the first cell structure CELL1, and the second through-metal pattern 472d may be formed at an upper end of the second upper chip UC2 including the second cell structure CELL2. The first through-electrode THV1 may be electrically connected to the first metal wiring 350c and the second metal wiring 360c. A lower via 371d may be formed between the first through-electrode THV1 and the first through-metal pattern 372d, and an upper via 471d may be formed between the second through-electrode THV2 and the second through-metal pattern 472d. The first through-metal pattern 372d and the second through-metal pattern 472d may be connected to each other in a bonding manner.

In addition, in the bit line bonding area BLBA, an upper metal pattern 252 may be formed on the uppermost metal layer of the peripheral circuit structure PERI, while an upper metal pattern 392 having the same form as that of the upper metal pattern 252 may be formed on the uppermost metal layer of the first cell structure CELL1. The upper metal pattern 392 of the first cell structure CELL1 and the upper metal pattern 252 of the peripheral circuit structure PERI may be electrically connected to each other in a bonding manner. In the bit line bonding area BLBA, the bit line 360c may be electrically connected to a page buffer included in the peripheral circuit structure PERI. For example, some of the circuit elements 220c of the peripheral circuit structure PERI may provide a page buffer, and the bit line 360c may be electrically connected to the circuit elements 220c that provide the page buffer via the upper bonding metal 370c of the first cell structure CELL1 and the upper bonding metal 270c of the peripheral circuit structure PERI.

Referring to FIG. 20, in the word line bonding area WLBA, the word lines 330 of the first cell structure CELL1 may extend in the first direction X parallel to the upper surface of the fourth substrate 310, and may be connected to a plurality of cell contact plugs 341 to 347 and 340. The first metal wiring 350b and the second metal wiring 360b may be disposed on top of and be sequentially connected to the cell contact plugs 340 connected to the word lines 330. The cell contact plugs 340 may be connected to the peripheral circuit structure PERI via the upper bonding metal 370b of the first cell structure CELL1 and the upper bonding metal 270b of the peripheral circuit structure PERI in the word line bonding area WLBA.

The cell contact plugs 340 may be electrically connected to the row decoder included in the peripheral circuit structure PERI. For example, some of the circuit elements 220b of the peripheral circuit structure PERI may provide the row decoder, and the cell contact plugs 340 may be electrically connected to the circuit elements 220b constituting the row decoder via the upper bonding metal 370b of the first cell structure CELL1 and the upper bonding metal 270b of the peripheral circuit structure PERI. In some implementations, an operating voltage of the circuit elements 220b constituting the row decoder may be different from an operating voltage of the circuit elements 220c constituting the page buffer. For example, the operating voltage of the circuit elements 220c constituting the page buffer may be greater than the operating voltage of the circuit elements 220b constituting the row decoder.

Similarly, in the word line bonding area WLBA, the word lines 430 of the second cell structure CELL2 may extend along the first direction X parallel to the upper surface of the fifth substrate 410 and may be connected to a plurality of cell contact plugs 441 to 447 and 440. The cell contact plugs 440 may be connected to the peripheral circuit structure PERI via the upper metal pattern of the second cell structure CELL2, the lower metal pattern and the upper metal pattern of the first cell structure CELL1, and the cell contact plug 348.

In the word line bonding area WLBA, the upper bonding metal 370b may be formed in the first cell structure CELL1, and the upper bonding metal 270b may be formed in the peripheral circuit structure PERI. The upper bonding metal 370b of the first cell structure CELL1 and the upper bonding metal 270b of the peripheral circuit structure PERI may be electrically connected to each other in a bonding manner. Each of the upper bonding metal 370b and the upper bonding metal 270b may be made of aluminum, copper, tungsten, or the like.

In the external pad peripheral area PA, a lower metal pattern 371e may be disposed under the first cell structure CELL1, and an upper metal pattern 472a may be disposed on top of the second cell structure CELL2. The lower metal pattern 371e of the first cell structure CELL1 and the upper metal pattern 472a of the second cell structure CELL2 may be connected to each other in a bonding manner in the outer pad peripheral area PA. Similarly, an upper metal pattern 372a may be formed on the first cell structure CELL1, and an upper metal pattern 272a may be formed on the peripheral circuit structure PERI. The upper metal pattern 372a of the first cell structure CELL1 and the upper metal pattern 272a of the peripheral circuit structure PERI may be connected to each other in a bonding manner.

Common source line contact plugs 380 and 480 may be disposed in the external pad peripheral area PA. The common source line contact plugs 380 and 480 may be made of a conductive material such as a metal, a metal compound, or doped polysilicon. The common source line contact plug 380 of the first cell structure CELL1 may be electrically connected to the common source line 320, and the common source line contact plug 480 of the second cell structure CELL2 may be electrically connected to the common source line 420. A first metal wiring 350a and a second metal wiring 360a may be sequentially stacked on the common source line contact plug 380 of the first cell structure CELL1, while a first metal wiring 450a and a second metal wiring 460a may be sequentially stacked on the common source line contact plug 480 of the second cell structure CELL2.

Input/output pads 205, 405, and 406 may be disposed in the external pad peripheral area PA. Referring to FIG. 20, a lower insulation film 201 may cover a lower surface of a third substrate 210, and a first input/output pad 205 may be formed on the lower insulation layer 201. The first input/output pad 205 may be connected to at least one of the plurality of circuit elements 220a disposed in the peripheral circuit structure PERI via the first input/output contact plug 203, and may be electrically insulated from the third substrate 210 via the lower insulating film 201. In addition, a side insulating film may be disposed between the first input/output contact plug 203 and the third substrate 210 so as to electrically insulate the first input/output contact plug 203 from the third substrate 210.

An upper insulating layer 401 covering an upper surface of the fifth substrate 410 may be formed on the fifth substrate 410. The second input/output pad 405 and/or the third input/output pad 406 may be disposed on the upper insulating film 401. The second input/output pad 405 may be connected to at least one of the plurality of circuit elements 220a disposed in the peripheral circuit structure PERI via the second input/output contact plugs 403 and 303. The third input/output pad 406 may be connected to at least one of the plurality of circuit elements 220a disposed in the peripheral circuit structure PERI via the third input/output contact plugs 404 and 304.

In some implementations, the fifth substrate 410 may not be disposed in an area where the input/output contact plug is disposed. For example, as illustrated in FIGS. 22A and 22B, the third input/output contact plug 404 may be isolated from the fifth substrate 410 in a direction parallel to the upper surface of the fifth substrate 410, and may extend through the interlayer insulating film 415 of the second cell structure CELL2 so as to be connected to the third input/output pad 406. In this case, the third input/output contact plug 404 may be formed in various processes.

For example, as illustrated in FIG. 22A, the third input/output contact plug 404 may extend in the third direction Z, and may be formed to have a diameter gradually increasing as the third input/output contact plug 404 extends toward the upper insulating layer 401. That is, the diameter of the channel structure CH described in FIG. 21A may be formed to be smaller as the channel structure CH extends toward the upper insulating film 401, whereas the diameter of the third input/output contact plug 404 may be larger as the third input/output contact plug 404 extends toward the upper insulating film 401. For example, the third input/output contact plug 404 may be formed after the second cell structure CELL2 and the first cell structure CELL1 have been coupled to each other in a bonding manner.

In addition, as an example, as illustrated in FIG. 22B, the third input/output contact plug 404 may extend in the third direction Z, and may be formed to have a diameter gradually decreasing as the third input/output contact plug 404 extends toward the upper insulating film 401. That is, the diameter of the third input/output contact plug 404 may decrease as the third input/output contact plug 404 extends toward the upper insulating film 401 as the channel structure CH does. For example, the third input/output contact plug 404 may be formed together with the cell contact plugs 440 before bonding of the second cell structure CELL2 and the first cell structure CELL1 to each other.

In another implementation, the input/output contact plug may be disposed to overlap the fifth substrate 410. For example, as illustrated in FIGS. 23A to 23C, the second input/output contact plug 403 may be formed to extend through the interlayer insulating film 415 of the second cell structure CELL2 in the third direction Z, and may extend through the fifth substrate 410 so as to be electrically connected to the second input/output pad 405. In this case, a connection structure between the second input/output contact plug 403 and the second input/output pad 405 may be implemented in various ways.

For example, as illustrated in FIG. 23A, an opening 408 extending through the fifth substrate 410 may be formed, and the second input/output contact plug 403 may pass through the opening 408 formed in the fifth substrate 410 so as to be directly connected to the second input/output pad 405. In this case, as illustrated in FIG. 23A, a diameter of the second input/output contact plug 403 may increase as the second input/output contact plug 403 extends toward the second input/output pad 405. However, this is merely an example, and the diameter of the second input/output contact plug 403 may gradually decrease as the second input/output contact plug 403 extends toward the second input/output pad 405.

For example, as illustrated in FIG. 23B, the opening 408 extending through the fifth substrate 410 may be formed, and a contact 407 may be formed in the opening 408. One end of the contact 407 may be connected to the second input/output pad 405, and the other end thereof may be connected to the second input/output contact plug 403. Accordingly, the second input/output contact plug 403 may be electrically connected to the second input/output pad 405 via the contact 407 in the opening 408. In this case, as illustrated in FIG. 23B, a diameter of the contact 407 may increase toward as the contact 407 extends toward the second input/output pad 405, and a diameter of the second input/output contact plug 403 may decrease as the second input/output contact plug 403 extends toward the second input/output pad 405. For example, the second input/output contact plug 403 may be formed together with the cell contact plugs 440 before bonding of the second cell structure CELL2 and the first cell structure CELL1 to each other. The contact 407 may be formed after bonding of the second cell structure CELL2 and the first cell structure CELL1 to each other.

In addition, in an example, as illustrated in FIG. 23C, a stopper 409 may be further formed on an upper surface of the opening 408 of the fifth substrate 410 compared to FIG. 23B. The stopper 409 may be a metal wiring formed in the same layer as a layer of the common source line 420. However, this is merely an example, and the stopper 409 may be a metal wiring formed in the same layer as a layer of at least one of the word lines 430. The second input/output contact plug 403 may be electrically connected to the second input/output pad 405 via the contact 407 and the stopper 409.

In a similar manner to the second and third input/output contact plugs 403 and 404 of the second cell structure CELL2, each of the second and third input/output contact plugs 303 and 304 of the first cell structure CELL1 may be formed to have a diameter that decreases as each of the second and third input/output contact plugs 303 and 304 extends toward the lower metal pattern 371e or that increases as each of the second and third input/output contact plugs 303 and 304 extends toward the lower metal pattern 371e.

In one example, according to implementations, a slit 411 may be formed in the fifth substrate 410. For example, the slit 411 may be formed at any position of the external pad peripheral area PA. In an example, as illustrated in FIGS. 24A to 24C, the slit 411 may be positioned between the second input/output pad 405 and the cell contact plugs 440 in a plan view. However, this is merely an example, and in a plan view, the slit 411 may be formed such that the second input/output pad 405 is positioned between the slit 411 and the cell contact plugs 440.

For example, as illustrated in FIG. 24A, the slit 411 may be formed to extend through the fifth substrate 410. The slit 411 may be used, for example, to prevent the fifth substrate 410 from being finely broken when the opening 408 is formed. However, this is merely an example, and the slit 411 may be formed to have a depth of about 60 to 70% of a thickness of the fifth substrate 410.

In addition, in an example, as illustrated in FIG. 24B, a conductive material 412 may be formed in the slit 411. The conductive material 412 may be used, for example, to discharge a leakage current generated during the operation of circuit elements in the external pad peripheral area PA to the outside. In this case, the conductive material 412 may be connected to an external ground line.

In addition, in an example, as illustrated in FIG. 24C, an insulating material 413 may be formed in the slit 411. The insulating material 413 may be formed, for example, to electrically insulate the second input/output pad 405 and the second input/output contact plug 403 disposed in the external pad area PA from the word line bonding area WLBA. The insulating material 413 may be formed in the slit 411, thereby preventing a voltage provided via the second input/output pad 405 from affecting the metal layer disposed on the fifth substrate 410 in the word line bonding area WLBA.

In one example, according to some implementations, the first to third input/output pads 205, 405, and 406 may be optionally formed. For example, the semiconductor memory device 500 may be implemented to include only the first input/output pad 205 disposed on the third substrate 210, only the second input/output pad 405 disposed on the fifth substrate 410, or only the third input/output pad 406 disposed on the upper insulating film 401.

According to some implementations, at least one of the fourth substrate 310 of the first cell structure CELL1 and the fifth substrate 410 of the second cell structure CELL2 may be used as a sacrificial substrate, and may be entirely or partially removed before or after the bonding process. After the substrate has been removed, an additional film may be stacked. For example, the fourth substrate 310 of the first cell structure CELL1 may be removed before or after the peripheral circuit structure PERI and the first cell structure CELL1 are bonded to each other, and an insulating film covering the upper surface of the common source line 320 or a conductive film for connection thereto may be formed. Similarly, the fifth substrate 410 of the second cell structure CELL2 may be removed before or after the bonding of the first cell structure CELL1 and the second cell structure CELL2 to each other, and an upper insulating film 401 covering the upper surface of the common source line 420 or a conductive film for connection thereto may be formed.

Hereinafter, an electronic system including a semiconductor memory device according to some implementations will be described with reference to FIGS. 1 to 27.

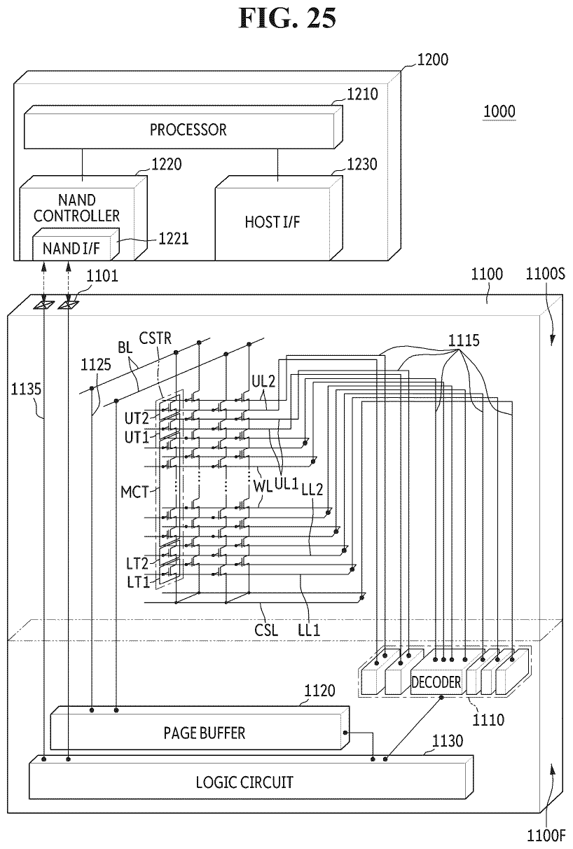

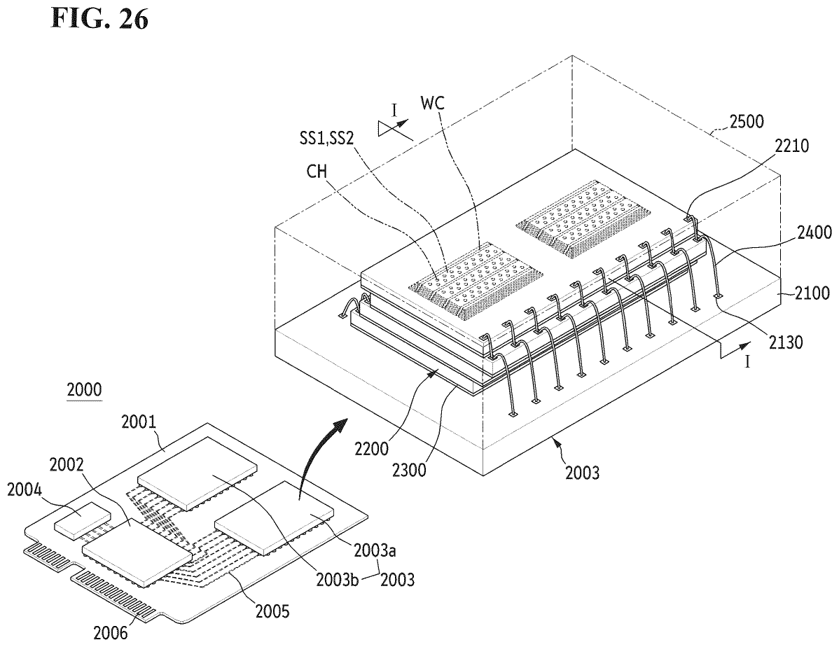

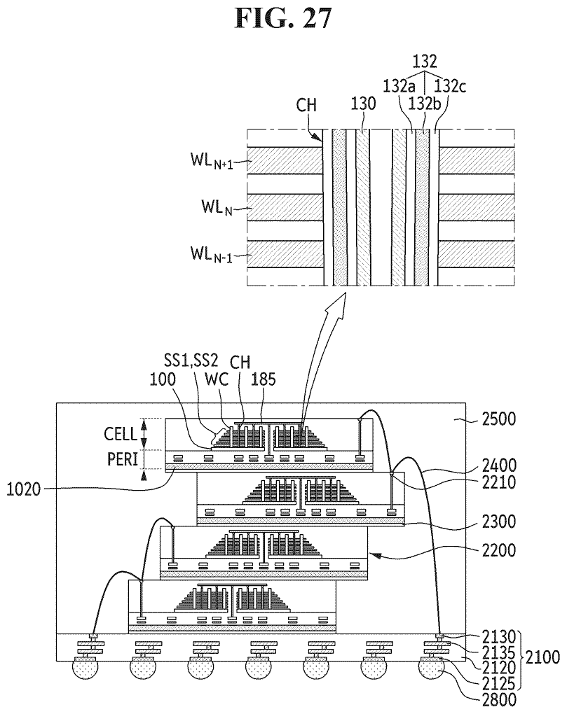

FIG. 25 is an example block diagram for illustrating an electronic system according to some implementations. FIG. 26 is an example perspective view illustrating an electronic system according to some implementations. FIG. 27 is a schematic cross-sectional view taken along a line I-I of FIG. 26. For convenience of description, contents duplicate with those described above using FIGS. 1 to 24c will be briefly described or descriptions thereof will be omitted.

Referring to FIG. 25, an electronic system 1000 according to some implementations may include a semiconductor memory device 1100 and a controller 1200 electrically connected to the semiconductor memory device 1100. The electronic system 1000 may be a storage device storage device including one or a plurality of semiconductor devices 1100 or an electronic device electronic device including the storage device. For example, the electronic system 1000 may be embodied as a solid state drive device (SSD), a Universal Serial Bus (USB), a computing system, a medical device, or a communication device including one or a plurality of semiconductor memory devices 1100.

The semiconductor memory device 1100 may be embodied as a non-volatile memory device (e.g., a NAND flash memory device). The semiconductor memory device 1100 may be embodied, as for example, at least one of the semiconductor devices as described above with reference to FIGS. 1 to 24C. The semiconductor memory device 1100 may include a first structure 1100F and a second structure 1100S on the first structure 1100F.

The first structure 1100F may be a peripheral circuit structure including a decoder circuit 1110 (e.g., the row decoder 33 of FIG. 1), a page buffer 1120 (e.g., the page buffer 35 of FIG. 1), and a logic circuit 1130 (e.g., the control circuit 37 of FIG. 1). The first structure 1100F may be embodied as, for example, the peripheral circuit structure PERI as described above with reference to FIGS. 1 to 24C.

The second structure 1100S may be a memory cell structure including bit lines BL, a common source line CSL, word lines WL, first and second gate upper lines UL1 and UL2, first and second gate lower lines LL1 and LL2, and memory cell strings CSTR between the bit lines BL and the common source line CSL. The second structure 1100S may correspond to the memory cell structure CELL described above using, for example, FIGS. 1 to 24C.

In the second structure 1100S, each of the memory cell strings CSTR may include lower transistors LT1 and LT2 adjacent to the common source line CSL, upper transistors UT1 and UT2 adjacent to the bit lines BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to implementations.

In some implementations, the upper transistors UT1 and UT2 may include a string select transistor SST, and the lower transistors LT1 and LT2 may include a ground select transistor GST. The gate lower lines LL1 and LL2 may be gate electrodes of the lower transistors LT1 and LT2, respectively. The word lines WL may be gate electrodes of the memory cell transistors MCT, respectively. The gate upper lines UL1 and UL2 may be gate electrodes of the upper transistors UT1 and UT2, respectively.

In some implementations, the lower transistors LT1 and LT2 may include a lower erase control transistor LT1 and a ground select transistor LT2 connected in series with each other. In some implementations, the upper transistors UT1 and UT2 may include a string select transistor UT1 and an upper erase control transistor UT2 which are connected in series with each other. At least one of the lower erase control transistor LT1 and the upper erase control transistor UT1 may be used for an erase operation of deleting data stored in the memory cell transistors MCT using a Gate Induce Drain Leakage (GIDL) phenomenon.

The common source line CSL, the first and second gate lower lines LL1 and LL2, the word lines WL, and the first and second gate upper lines UL1 and UL2 may be electrically connected to the decoder circuit 1110 via first connection lines 1115 extending from the first structure 1100F to the second structure 1100S. The bit lines BL may be electrically connected to the page buffer 1120 via second connection lines 1125 extending from the first structure 1100F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1000 may communicate with the controller 1200 via an input/output pad 1101 electrically connected to the logic circuit 1130. The input/output pad 1101 may be electrically connected to the logic circuit 1130 via an input/output connection wiring 1135 extending from the first structure 1100F to the second structure 1100S.

The controller 1200 may include a processor 1210, an NAND controller 1220, and a host interface 1230. In some implementations, the electronic system 1000 may include a plurality of semiconductor memory devices 1100, and in this case, the controller 1200 may control the plurality of semiconductor memory devices 1100.

The processor 1210 may control overall operations of the electronic system 1000 including the controller 1200. The processor 1210 may operate based on predefined firmware, and may control the NAND controller 1220 to access the semiconductor memory device 1100. The NAND controller 1220 may include a NAND interface 1221 that processes communication with the semiconductor memory device 1100. Via the NAND interface 1221, a control command for controlling the semiconductor memory device 1100, data to be written to memory cell transistors MCT of the semiconductor memory device 1100, and data to be read from the memory cell transistors MCT of the semiconductor memory device 1100 may be transmitted. The host interface 1230 may provide a communication function between the electronic system 1000 and an external host. Upon receiving a control command from an external host via the host interface 1230, the processor 1210 may control the semiconductor memory device 1100 in response to the control command.

Referring to FIG. 26 and FIG. 27, an electronic system according to some implementations may include a main substrate 2001, a main controller 2002 mounted on the main substrate 2001, at least one semiconductor package 2003, and at least one DRAM 2004. The semiconductor package 2003 and the DRAM 2004 may be connected to the main controller 2002 via line patterns 2005 formed on the main substrate 2001.

The main substrate 2001 may include a connector 2006 including a plurality of pins coupled to an external host. The number and an arrangement of the plurality of pins in the connector 2006 may vary based on a communication interface between the electronic system 2000 and the external host. In some implementations, the electronic system 2000 may communicate with the external host using one of interfaces such as USB (Universal Serial Bus), PCI-Express (Peripheral Component Interconnect Express), SATA (Serial Advanced Technology Attachment), M-Phy for UFS (Universal Flash Storage), etc. In some implementations, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may improve an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a bottom face of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may be embodied as the input/output pad 1101 in FIG. 16.

In some implementations, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In some implementations, in each of the first semiconductor package 2003a and the second semiconductor package 2003b, the semiconductor chips 2200 may be electrically connected to each other via a connection structure including a through electrode (Through Silicon Via: TSV) instead of the connection structure 2400 using the bonding wire scheme.

In some implementations, the main controller 2002 and the semiconductor chips 2200 may be included in one package. In some implementations, the main controller 2002 and the semiconductor chips 2200 may be mounted on a separate interposer substrate different from the main substrate 2001, and the main controller 2002 and the semiconductor chips 2200 may be connected to each other via a line formed in the interposer substrate.

In some implementations, the package substrate 2100 may be embodied as a printed circuit board. The package substrate 2100 may include a package substrate body 2120, the package upper pads disposed on a top face of the package substrate body 2120, package lower pads 2125 disposed on a bottom face of the package substrate body 2120, or exposed through the bottom face thereof, and internal lines 2135 disposed in the package substrate body 2120 so as to electrically connect the upper pads 2130 and the lower pads 2125 to each other. The upper pads 2130 may be electrically connected to the connection structures 2400. The lower pads 2125 may be connected to the line patterns 2005 of the main substrate 2010 of the electronic system 2000 via conductive connectors 2800 as shown in FIG. 26.

In the electronic system according to some implementations, each of the semiconductor chips 2200 may include the semiconductor memory device described above using FIGS. 1 to 24C. For example, each of the semiconductor chips 2200 may include the peripheral circuit structure PERI and the memory cell structure CELL stacked on the peripheral circuit structure PERI. For example, the memory cell structure CELL may include the first substrate 100, the stack structure SS1 and SS2, the channel structure CH, the cutting pattern WC, and the conductive line 185 as described above with reference to FIGS. 1 to 5. In addition, for example, the peripheral circuit structure PERI may include the second substrate 1020 and the peripheral circuit element PT described above using FIGS. 1 to 5.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although implementations of the present disclosure have been described with reference to the accompanying drawings, the present disclosure is not limited to the above implementations, but may be implemented in various different forms. A person skilled in the art may appreciate that the present disclosure may be practiced in other concrete forms without changing the technical spirit or essential characteristics of the present disclosure. Therefore, it should be appreciated that the implementations as described above are not restrictive but illustrative in all respects.

What is claimed is:

1. A semiconductor memory device comprising:
a plurality of word lines spaced apart from each other in a first direction;
a semiconductor pattern extending in the first direction and intersecting the plurality of word lines;
a data storage pattern between the plurality of word lines and the semiconductor pattern, wherein the data storage pattern includes a ferroelectric material;
a common source line under the plurality of word lines and connected to the semiconductor pattern;
a bit line on the plurality of word lines; and
a channel pad through which the semiconductor pattern and the bit line are connected to each other,
wherein each of the common source line and the channel pad includes a P-type semiconductor material.

2. The semiconductor memory device of claim 1, wherein the ferroelectric material includes hafnium (Hf).

3. The semiconductor memory device of claim 1, wherein the P-type semiconductor material includes polysilicon doped with P-type impurities.

4. The semiconductor memory device of claim 3, wherein the P-type impurities include at least one of boron (B), aluminum (Al), gallium (Ga), or indium (In).

5. The semiconductor memory device of claim 1, wherein the semiconductor pattern includes undoped silicon.

6. The semiconductor memory device of claim 1, comprising a cutting pattern extending in a second direction intersecting the first direction,
wherein the plurality of word lines are divided by the cutting pattern.

7. The semiconductor memory device of claim 6, wherein the bit line extends in a third direction intersecting both the first direction and the second direction.

8. The semiconductor memory device of claim 1, wherein the common source line is in contact with a side surface of the semiconductor pattern.

9. The semiconductor memory device of claim 1, wherein the common source line is in contact with a lower surface of the semiconductor pattern.

10. A method for operating a semiconductor memory device, wherein the semiconductor memory device includes:
a plurality of word lines spaced apart from each other in a first direction;
a semiconductor pattern extending in the first direction and intersecting the plurality of word lines;
a data storage pattern between the plurality of word lines and the semiconductor pattern, wherein the data storage pattern includes a ferroelectric material; and
a bit line on the plurality of word lines and connected to the semiconductor pattern, the method comprising:
applying a negative erase voltage to the plurality of word lines to perform an erase operation on a plurality of memory cells corresponding to the plurality of word lines;
applying a verification voltage to the plurality of word lines; and
terminating the erase operation based on a current equal to or greater than a reference current being detected in the bit line as a result of the application of the verification voltage,
wherein the semiconductor pattern is configured to form a P-type channel.

11. The method of claim 10, comprising:
repeating the erase operation based on the current equal to or greater than the reference current not being detected in the bit line as a result of the application of the verification voltage.

12. The method of claim 10, wherein the semiconductor memory device includes a plurality of cutting patterns,
wherein each of the plurality of cutting patterns extends in a second direction intersecting the first direction, and the plurality of word lines are divided by the cutting patterns,
wherein the plurality of word lines form a plurality of memory cell blocks isolated from each other via the plurality of cutting patterns,
wherein the erase operation is individually performed on each of the memory cell blocks.

13. The method of claim 10, wherein the verification voltage has a positive (+) value.

14. The method of claim 10, comprising:
applying a positive program voltage to a selected word line among the plurality of word lines to perform a program operation on a target memory cell corresponding to the selected word line.

15. The method of claim 10, comprising:
applying a negative read voltage to a selected word line among the plurality of word lines to perform a read operation on a target memory cell corresponding to the selected word line.

16. An electronic system comprising:
a substrate;
a semiconductor memory device on the substrate; and
a controller electrically connected to the semiconductor memory device,
wherein the semiconductor memory device includes:
a plurality of word lines spaced apart from each other in a first direction;
a semiconductor pattern extending in the first direction and intersecting the plurality of word lines;
a data storage pattern between the plurality of word lines and the semiconductor pattern, wherein the data storage pattern includes a ferroelectric material;
a common source line under the plurality of word lines and connected to the semiconductor pattern; and
a bit line on the plurality of word lines,
wherein the semiconductor pattern is configured to form a P-type channel.

17. The electronic system of claim 16, wherein the ferroelectric material includes hafnium (Hf).

18. The electronic system of claim 16, wherein semiconductor memory device includes a channel pad through which the semiconductor pattern and the bit line are connected to each other,
wherein each of the common source line and the channel pad includes a P-type semiconductor material.

19. The electronic system of claim 16, wherein the controller is configured to apply a negative erase voltage to the plurality of word lines to perform an erase operation on a plurality of memory cells corresponding to the plurality of word lines.

20. The electronic system of claim 19, wherein the controller is configured to:
apply a verification voltage to the plurality of word lines; and
terminate the erase operation based on a current equal to or greater than a reference current being detected in the bit line as a result of the application of the verification voltage.
